(19) United States
(12) Patent Application Publication
(10) Pub. No.: US 2026/0162680 A1
(43) Pub. Date: Jun. 11, 2026

(54) MAGNETIC DISK DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Atsushi Namikawa, Yokohama Kanagawa (JP); Yukio Urata, Sagamihara Kanagawa (JP)

(21) Appl. No.: 19/181,709

(22) Filed: Apr. 17, 2025

(30) Foreign Application Priority Data
Sep. 2, 2024 (JP) 2024-150838

(51) Int. Cl. G11B 20/18; H03M 13/00; H03M 13/11

(52) U.S. Cl. CPC G11B 20/1833; H03M 13/1111; H03M 13/611

(57) ABSTRACT

According to one embodiment, a magnetic disk device includes a disk, a write head, a volatile buffer memory, a parity generation unit, a write processing unit, an error correction unit, a storage processing unit, and a conventional correction limit prediction unit. The parity generation unit generates first conventional parity, first potential parity, second conventional parity and second potential parity. The storage processing unit overwrites the second potential parity to a first recoding area if the first prediction information is normal information, and leaves the first potential parity in the first recording area and stores the second potential parity in a second recording area if the first prediction information is replaced with abnormal information.

### CROSS-REFERENCE TO RELATED APPLICATIONS

This application is based upon and claims the benefit of priority from Japanese Patent Application No. 2024-150838, filed Sep. 2, 2024, the entire contents of which are incorporated herein by reference.

### FIELD

Embodiments described herein relate generally to a magnetic disk device.

### BACKGROUND

Magnetic disk devices such as a Conventional Magnetic Recording (CMR) (or conventional recording) magnetic disk device that writes data to a plurality of tracks at intervals in the radial direction of the disk, a Shingled Magnetic Recording (SMR) magnetic disk device that overwrites data to a plurality of tracks in the radial direction of the disk, and a hybrid recording type magnetic disk device that selectively executes the conventional magnetic recording and the shingled magnetic recording, are known.

### BRIEF DESCRIPTION OF THE DRAWINGS

FIG. 1 is a block diagram showing a configuration of a magnetic disk device according to an embodiment.

FIG. 2 is a perspective view showing parts of the magnetic disk device, illustrating a plurality of disks and a plurality of heads.

FIG. 3 is a schematic diagram showing an example of arrangement of a plurality of servo areas and a plurality of data areas on a single disk according to the embodiment.

FIG. 4 is a schematic diagram showing three tracks in the user data area where shingled magnetic recording processing of the disk shown in FIG. 3 is executed, together with a write head.

FIG. 5 is a schematic diagram showing three tracks of a media cache where conventional magnetic recording processing of the disk shown in FIG. 3 is executed, together with a write head.

FIG. 6 is a schematic diagram showing an example of data write processing on the disk.

FIG. 7 is a schematic diagram showing two bands and one guard band of the user data area shown in FIG. 6.

FIG. 8 is a schematic diagram showing three sectors of one track of the band shown in FIG. 6.

FIG. 9 is a schematic diagram showing two bands and one guard band shown in FIG. 7, illustrating a plurality of target sectors and a plurality of unused sectors.

FIG. 10 is a schematic diagram showing five data tracks in the recording layer of the disk shown in FIG. 2.

FIG. 11 is a block diagram showing a configuration of a part of the magnetic disk device, and a configuration of a write channel, and the like.

FIG. 12 is a schematic diagram showing an example of the first track and the second track in a case where it is assumed that the above-described magnetic disk device does not comprise a function of executing track-based error correction for track data, illustrating the write processing for the first track and the second track, illustrating a state in which the write processing for the second track is continued until the sector-based error correction for the first track reaches its limit, and illustrating each of the change in BER for the first track and the change in BER for the positioning error in graph form.

FIG. 13 is a schematic diagram showing an example of the first track and second track in a case where it is assumed that the magnetic disk device does not comprise a function of executing track-based error correction for the track data, illustrating the write processing for the first track and the second track, illustrating a state in which a determination value is set to a write-off track slice smaller (more severe) than the track margin and the write processing for the second track is ended when a positioning error is more than or equal to a write-off track slice, and illustrating each of the change in BER for the first track and the change in BER for the positioning error in graph form.

FIG. 14 is a schematic diagram showing an example of the first track and second track of a magnetic disk device that comprises a function of executing track-based error correction for the track data, illustrating the write processing for the first track and the second track, illustrating a state in which a determination value is set to a write-off track slice greater (more loose) than the track margin and the write processing for the second track is continued even after track-based conventional error correction for the first track reaches a limit, and illustrating each of the change in BER for the first track and the change in BER for the positioning error in graph form.

FIG. 15 is a flowchart showing a write processing method according to the embodiment, together with the generation of a potential parity and the storage of the potential parity.

FIG. 16 is a flowchart showing the write processing method for the n-th data track, of the write processing method according to the embodiment, together with a method of storing a potential parity in a buffer memory.

FIG. 17 is a flowchart showing the write processing method following FIG. 16, together with the storing method.

FIG. 18 is a flowchart showing a method of saving the potential parity to a nonvolatile memory during a first idle period, in the embodiment.

FIG. 19 is a flowchart showing a method of saving the potential parity to a nonvolatile memory when the main power supply is lost, in the embodiment.

FIG. 20 is a schematic diagram showing five data tracks of the recording layer of the disk shown in FIG. 10, illustrating a state in which data is written to the n−2-th data track, n−1-th data track, and n-th data track in order, and illustrating a situation in which the write processing is ideally executed without positioning errors.

FIG. 21A is a table showing the recording area of the buffer memory, illustrating a method of storing the potential parity in the buffer memory corresponding to the write processing in FIG. 20, and illustrating a state in which the first potential parity is stored in the selected first recording area and then the selected first recording area is continuously selected.

FIG. 21B is a table showing the recording area of the buffer memory following FIG. 21A, illustrating a situation in which the second potential parity is overwritten to the selected first recording area and then the recording area selected in the buffer memory is advanced by one.

FIG. 21C is a table showing the recording area of the buffer memory, following FIG. 21B, illustrating a situation in which the selected recording area in the buffer memory is moved back by one.

FIG. 22 is a schematic diagram showing five data tracks of the recording layer of the disk shown in FIG. 10, illustrating a state in which data is written to the n−2-th data track, the n−1-th data track, and the n-th data track in order, and illustrating a situation in which the write processing is being executed on the n-th data track while the positioning error exceeds the first off-track slice.

FIG. 23A is a table showing the recording area of the buffer memory, illustrating a method of storing the potential parity in the buffer memory corresponding to the write processing in FIG. 22, and illustrating a situation in which the first potential parity is stored in the currently selected first recording area and then the recording area selected in the buffer memory is advanced by one.

FIG. 23B is a table showing the recording area of the buffer memory, following FIG. 23A, illustrating a situation in which the second potential parity is stored in the currently selected second recording area and then the recording area selected in the buffer memory is advanced by one.

FIG. 23C is a table showing the recording area of the buffer memory, following FIG. 23B, illustrating a situation in which the recording area selected in the buffer memory is moved back by one.

FIG. 24 is a schematic diagram showing five data tracks of the recording layer of the disk shown in FIG. 10, illustrates a state in which data is written to the n−2-th data track, n−1-th data track, and n-th data track in order, and illustrating a situation in which the write processing is being executed on the n-th data track while the positioning error exceeds the second off-track slice.

FIG. 25A is a table showing the recording area of the buffer memory, illustrating a method of storing the potential parity in the buffer memory corresponding to the write processing in FIG. 24, and illustrating a state in which the first potential parity is stored in the selected first recording area and then the selected first recording area is continuously selected.

FIG. 25B is a table showing the recording area of the buffer memory, following FIG. 25A, illustrating a situation in which the second potential parity is stored in the currently selected first recording area and then the recording area selected in the buffer memory is advanced by one.

FIG. 25C is a table showing the recording area of the buffer memory, following FIG. 25B, illustrating a situation in which the second recording area selected in the buffer memory is continuously selected.

### DETAILED DESCRIPTION

In general, according to one embodiment, there is provided a magnetic disk device comprising: a disk including a user data area including a first data track and a second data track continuous in a radial direction, in a recording layer, the first data track and the second data track each including a plurality of target sectors as targets to which data is written; a write head writing data to the recording layer of the disk; a volatile buffer memory; a parity generation unit; a write processing unit capable of executing write processing of writing data to the recording layer; an error correction unit executing error correction of data of a corrupted target sector in which data is determined to be corrupted among the plurality of target sectors of each of the first data track and the second data track; a storage processing unit; and a conventional correction limit prediction unit.

The write processing unit writes first user data to the plurality of target sectors of the first data track and uses the target sectors as a plurality of user data sectors, during a first write period, and writes second user data to the plurality of target sectors of the second data track and uses the target sectors as a plurality of user data sectors, during a second write period following the first write period. The parity generation unit generates first conventional parity and first potential parity for error correction of first corrupted data of one or more corrupted target sectors of the first data track, based on the first user data, and generates second conventional parity and second potential parity for error correction of second corrupted data of one or more corrupted target sectors of the second data track, based on the second user data. The ability of the first potential parity to execute the error correction of the first corrupted data is higher than the ability of the first conventional parity to execute the error correction of the first corrupted data. The ability of the second potential parity to execute the error correction of the second corrupted data is higher than the ability of the second conventional parity to execute the error correction of the second corrupted data.

The storage processing unit stores the first potential parity in the buffer memory, and then stores the second potential parity in the buffer memory. The conventional correction limit prediction unit generates first prediction information that is the information for predicting whether the first conventional error correction of the first corrupted data, which is executed using the first conventional parity by the error correction unit, reaches its limit after the second user data is written to the second data track. If the first prediction information is normal information for predicting that the first conventional error correction does not reach its limit, the storage processing unit maintains a recording area where the potential parity is stored, in the buffer memory, stores the second potential parity in the first recording area where the first potential parity is stored, in the buffer memory, and overwrites the second potential parity to the first recording area, and if the first prediction information is replaced with abnormal information for predicting that the first conventional error correction reaches its limit, the storage processing unit changes the recording area where the potential parity is stored, in the buffer memory, leaves the first potential parity in the first recording area, and stores the second potential parity in the second recording area which is different from the first recording area, in the buffer memory.

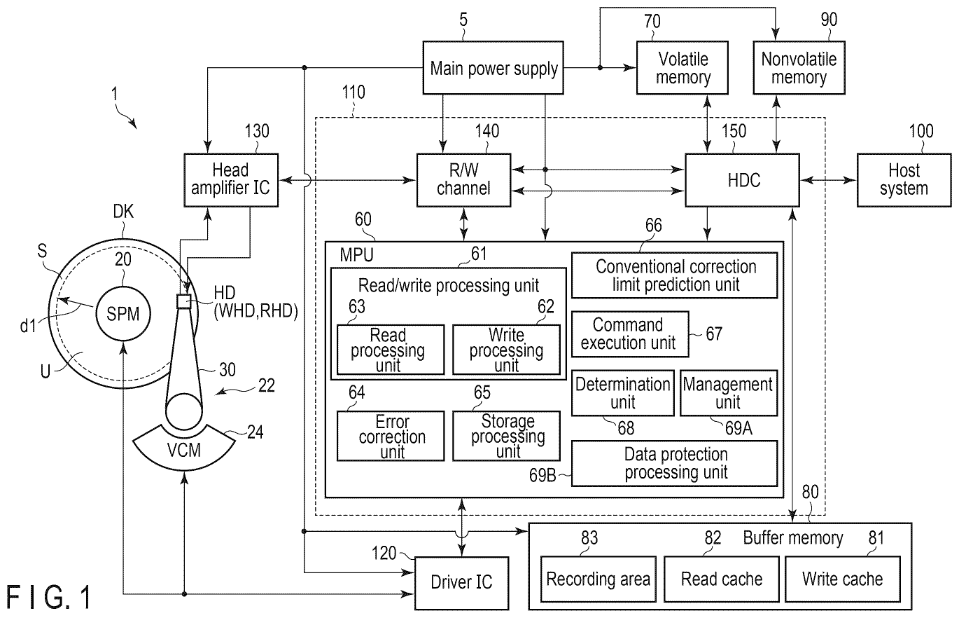

A magnetic disk device 1 according to one embodiment will be described hereinafter with reference to the accompanying drawings. First, a configuration of the magnetic disk device 1 will be described. FIG. 1 is a block diagram showing the configuration of the magnetic disk device 1 according to the embodiment. In the embodiment, the magnetic disk device 1 is a hybrid recording magnetic disk device that selectively executes the conventional magnetic recording and the shingled magnetic recording. However, a technique to be described below may be applied to a magnetic disk device of the shingled magnetic recording or a magnetic disk device of the conventional magnetic recording.

As shown in FIG. 1, the magnetic disk device 1 comprises a plurality of, for example, one to ten disks (magnetic disks) DK serving as recording media, a main power supply 5, a spindle motor (SPM) 20 serving as a drive motor, a head stack assembly 22, a driver IC 120, a head amplifier integrated circuit (hereinafter referred to as a head amplifier IC or preamplifier) 130, a volatile memory 70, a buffer memory (buffer) 80, a nonvolatile memory 90, and a system controller 110 that is a single-chip integrated circuit. In addition, the magnetic disk device 1 is connected to a host system (hereinafter simply referred to as a host) 100.

Each of the disks DK is formed to have a diameter of, for example, 97 mm (3.8 inches) and has recording layers (magnetic recording layers) on both sides. Incidentally, in the embodiment, the magnetic disk device 1 comprises one to eleven disks DK, but the number of disks DK is not limited to this.

The head stack assembly 22 can control a head HD mounted on an arm 30 to move, i.e., seek to a target position on the disk DK by driving a voice coil motor (hereinafter referred to as VCM) 24. The VCM 24 functions as an actuator.

A user data area U that can be used by the user, and a system area S where information necessary for the system management is written are assigned to the area of the disk DK where the data can be written.

The head HD records and reproduces information on the disk DK. The head HD comprises a slider as a main body, and comprises a write head WHD and a read head RHD mounted on the slider. The write head WHD writes the data to the recording layer of the disk DK. The read head RHD reads the data from data tracks of the recording layer of the disk DK.

The “central part of the head HD” may be referred to as the “head HD”, the “central part of the write head WHD” may be referred to as the “write head WHD”, and the “central part of the read head RHD” may be referred to as the “read head RHD”. The “central part of the write head WHD” may be simply referred to as the “head HD”, and the “central part of the read head RHD” may be simply referred to as the “head HD”.

The driver IC 120 controls driving the SPM 20 and the VCM 24 under control of the system controller 110 (more specifically, MPU 60 to be described below). The SPM 20 supports and rotates a plurality of disks DK.

The head amplifier IC 130 comprises a read amplifier and a write driver. The read amplifier amplifies a read signal read from the disk DK and outputs the amplified read signal to the system controller 110 (more specifically, a read/write (R/W) channel 140 to be described below). The write driver outputs a write current corresponding to a signal output from the R/W channel 140 to the head HD.

The volatile memory 70 is a semiconductor memory where the stored data is lost when power supply is cut off. The volatile memory 70 stores data necessary for processing in each unit of the magnetic disk device 1, and the like. The volatile memory 70 is a random access memory (RAM). The volatile memory 70 is, for example, a dynamic random access memory (DRAM). However, the volatile memory 70 may be a synchronous dynamic random access memory (SDRAM).

The buffer memory 80 is a semiconductor memory which temporarily records data transmitted and received between the magnetic disk device 1 and the host 100, and the like. Incidentally, the buffer memory 80 may be formed integrally with the volatile memory 70. The buffer memory 80 is a volatile RAM. Examples of the buffer memory 90 are a DRAM, a static random access memory (SRAM), an SDRAM, a ferroelectric random access memory (FeRAM), a magnetoresistive random access memory (MRAM), or the like.

The buffer memory 80 includes an area used as a write cache 81 and an area used as a read cache 82, and temporarily stores commands and the like, which are received from the host 100. The buffer memory 80 further includes a recording area 83. Write data including write commands and user data corresponding to the write commands is written to the write cache 81, and the write cache 81 temporarily stores the write data. Read commands are written to the read cache 82, and the read cache 82 temporarily stores the read commands.

The nonvolatile memory 90 is a semiconductor memory which records data stored even when power supply is cut off. The nonvolatile memory 90 is, for example, a NAND flash read only memory (FROM). However, the nonvolatile memory 90 may also be a NOR FROM.

The system controller (controller) 110 is realized by using, for example, a large scale integrated circuit (LSI) referred to as a system-on-a-chip (SoC) in which a plurality of elements are integrated on a single chip. The system controller 110 includes a read/write (R/W) channel 140, a hard disk controller (HDC) 150, and a microprocessor (MPU) 60. The system controller 110 is electrically connected to the driver IC 120, the head amplifier IC 130, the volatile memory 70, the buffer memory 80, the nonvolatile memory 90, and the host 100.

The R/W channel 140 executes signal processing of read data transferred from the disk DK to the host 100 and write data transferred from the host 100 in accordance with instructions from the MPU 60 to be described below. The R/W channel 140 comprises a circuit or function of modulating the write data. In addition, the R/W channel 140 comprises a circuit or a function of measuring the signal quality of the read data. The R/W channel 140 is electrically connected to, for example, the head amplifier IC 130, the HDC 150, the MPU 60 and the like.

The HDC 150 controls data transfer between the host 100 and the R/W channel 40 in accordance with instructions from the MPU 60, which will be described later. The HDC 150 is electrically connected to, for example, the R/W channel 140, the MPU 60, the volatile memory 70, the buffer memory 80, the nonvolatile memory 90, and the like.

The HDC 50 includes a gate generation unit. In accordance with commands from the host 100, instructions from the MPU 60, and the like, the gate generation unit generates various gates, for example, a write gate, a read gate, a servo gate, and the like and outputs the gates to the R/W channel 140, for example, the gate detection unit. In the following descriptions, “activating a predetermined gate” may be referred to as “asserting a predetermined gate”. In addition, “falling down a predetermined gate” may be referred to as “negating the predetermined gate”. In addition, “asserting a predetermined gate” and “negating a predetermined gate” may imply the meaning “generating a predetermined gate”. Incidentally, the gate generation unit may be included in the R/W channel 140 or the MPU 60.

The R/W channel 140 includes a gate detection unit. The gate detection unit detects whether various gates, for example, the write gate, the read gate, the servo gate, and the like are in an asserted state or a negated state.

For example, the gate detection unit executes the write processing when detecting that the write gate is asserted, and suspends (stops) the write processing when detecting that the write gate is negated.

In addition, the gate detection unit executes the read processing when detecting that the read gate is asserted, and stops the read processing when detecting that the read gate is negated. The gate detection unit executes the servo read processing when detecting that the servo gate is asserted, and stops the servo read processing when detecting that the servo gate is negated. Incidentally, the gate detection unit may be provided inside the HDC 150 or the MPU 60.

The MPU 60 is a control unit or main controller which controls each of units of the magnetic disk device 1. The MPU 60 controls the VCM 24 via the driver IC 120 to execute servo control for positioning the head HD. The MPU 60 controls the operation of writing the data to the disk DK and selects a storage destination of the write data transferred from the host 100. In addition, the MPU 60 controls the operation of reading the data from the disk DK and controls the processing of the read data transferred from the disk DK to the host 100. The MPU 60 is connected to each of units of the magnetic disk device 1. The MPU 60 is electrically connected to, for example, the driver IC 120, the R/W channel 140, the HDC 150 and the like.

The MPU 60 comprises a read/write processing unit 61, an error correction unit 64, a storage processing unit 65, a conventional correction limit prediction unit 66, a command execution unit 67, a determination unit 68, a management unit 69A, a data protection processing unit 69B, and the like. The MPU 60 executes processing of these units, for example, the read/write processing unit 61, the error correction unit 64, the storage processing unit 65, the conventional correction limit prediction unit 66, the command execution unit 67, the determination unit 68, the management unit 69A, the data protection processing unit 69B, and the like on firmware. Incidentally, the MPU 60 may comprise each of these units as a circuit.

The read/write processing unit 61 includes a write processing unit 62 and a read processing unit 63. In accordance with commands from the host 100, the write processing unit 62 controls the data write processing, and the read processing unit 63 controls the data read processing, causing the read head RHD to execute reading the data from the disk DK. The write processing unit 62 is capable of executing write processing to write data to the recording layer of the disk DK. The read/write processing unit 61 controls the VCM 24 via the driver IC 120, positions the head HD at a target position (predetermined radial position) on the disk DK, and executes the read processing or the write processing.

The main power supply 5 which is the power supply of the magnetic disk device 1 is connected to the driver IC 120, the head amplifier IC 130, the R/W channel 140, the HDC 150, the MPU 60, the volatile memory 70, the nonvolatile memory 90, and the buffer memory 80. The driver IC 120, the head amplifier IC 130, the R/W channel 140, the HDC 150, the MPU 60, the volatile memory 70, the nonvolatile memory 90, and the buffer memory 80 are driven with power supplied from the main power supply 5. The SPM 20 and the VCM 24 are driven with power supplied from the main power supply 5 via the driver IC 120.

The error correction unit 64 can execute the error correction of data of a corrupted sector (i.e., a corrupted target sector to be described below) in which data is determined to be corrupted, among the plurality of sectors (i.e., a plurality of target sectors to be described below) of the plurality of data tracks of the recording layer on the disk DK. The error correction unit 64 comprises a function of executing track-based error correction. The track-based error correction is also referred to as track-based error correction, track error checking and correcting (ECC), or the like.

Even if one or more corrupted target sectors occur in the data track by the write processing, the error correction unit 64 can execute the error correction (i.e., conventional error correction to be described below) of the data in one or more corrupted target sectors, based on the user data and a parity (i.e., a conventional parity to be described below) read from the data track, restore the data track, and rewrite the restored data to the data track. It is possible to allow the occurrence of corrupted target sectors in the data track during the write processing. Since it is difficult to end the write processing, degradation in the write performance of the magnetic disk device 1 can be suppressed.

The error correction unit 64 can use not only the conventional parity, but also a parity (i.e., a potential parity to be described below) having a higher ability to correct the data of corrupted target sectors than a conventional parity. Even if the conventional error correction of the data of one or more corrupted target sectors cannot be executed based on the user data and the conventional parity read from the data track, the error correction unit 64 can execute the error correction (i.e., potential error correction to be described below) of one or more elements of the corrupted data, based on the user data and the conventional parity read from the data track, and the potential parity, restore the data on the data track, and rewrite the restored data to the data track. It is possible to further allow the occurrence of corrupted target sectors on the data track during the write processing. The degradation in write performance of the magnetic disk device 1, which makes it further difficult to end the write processing, can be further suppressed.

The storage processing unit 65 can store the generated potential parity in the buffer memory 80.

In this example, three data tracks adjacent to the radial direction d1 among a plurality of data tracks of the recording layer of the disk DK are referred to as a first data track, a second data track, and a third data track. Then, it is assumed that the first user data and the first conventional parity are written to the first data track, then the second user data and the second conventional parity are written to the second data track, and the third user data and the third conventional parity are written to the third data track.

The conventional correction limit prediction unit 66 can generate the first prediction information, which is information for predicting whether the first conventional error correction of one or more elements of the corrupted data on the first data track using the first conventional parity by the error correction unit 64 may reach its limit after the second user data and the second conventional parity are written to the second data track. It is possible to determine whether excessive data has been written to the first data track side during the write processing targeting the second data track, and predict corruption which may occur in the data of the first data track, based on the first prediction information.

The conventional correction limit prediction unit 66 can generate the second prediction information, which is information for predicting whether the second conventional error correction of one or more elements of the corrupted data on the second data track using the second conventional parity by the error correction unit 64 may reach its limit after the second user data and the second conventional parity are written to the second data track. It is possible to determine whether excessive data has been written to the third data track side during the write processing targeting the second data track, and predict corruption which may occur in the data of the second data track during the write processing targeting the second data track, based on the second prediction information.

The command execution unit 67 can execute the write commands and read commands recorded in the buffer memory 80.

The determination unit 68 can determine whether there are any unexecuted commands in the buffer memory 80. For example, the determination unit 68 can determine a first idle period in which there are no unexecuted commands in the buffer memory 80. In addition, the determination unit 68 can also determine a second idle period in which there are no unexecuted commands in the buffer memory 80 after the first idle period.

The management unit 69A can include the potential parity before saving to the nonvolatile memory 90, in protection targets, and exclude the potential parity after saving to the nonvolatile memory 90 from the protection targets, among the potential parities stored in the recording area 83 of the buffer memory 80.

The data protection processing unit 69B can save the potential parity that the management unit 69A manages as a protection target to the nonvolatile memory 90 when the main power supply 5 is lost. The data protection processing unit 69B can execute power loss protection (PLP) processing that ensures the potential parity of the protection target in the buffer memory 80. Incidentally, the data protection processing unit 69B can also execute the PLP processing to ensure the write data in the buffer memory 80.

As described above, since the potential parity of the buffer memory 80 can be ensured by executing the PLP processing, the data in the data track where the potential error correction needs to be executed, of the recording layer of the disk DK, is indirectly ensured. In addition, the amount of data that can be stored in the buffer memory 80 can be increased in accordance with saving the data to the nonvolatile memory 90.

Incidentally, saving the potential parity of buffer memory 80 to the nonvolatile memory 90 may be executed not only when the main power supply 5 is lost, but also during idle periods.

The management unit 69A desirably includes the potential parity of the buffer memory 80, which has been saved to the nonvolatile memory 90, in the protection targets. As a result, the potential parity can be protected directly and indirectly in both the buffer memory 80 and the nonvolatile memory 90.

However, the potential parity of the buffer memory 80, which has been used by the execution of the potential error correction may be excluded from the protection targets or may be overwritten.

Next, the processing procedure of the data protection processing unit 69B at the time of recovering the main power supply 5, and the effects of the processing procedure will be described.

When the main power supply 5 is recovered after the main power supply 5 is lost, the data protection processing unit 69B can process as follows. The data protection processing unit 69B can write the potential parity saved to the nonvolatile memory 90 to the buffer memory 80 and restore the potential parity in the buffer memory 80. As a result, the magnetic disk device 1 can execute the potential error correction using the potential parity restored in the buffer memory 80.

In addition, the data protection processing unit 69B can also write the write data that has been saved to the nonvolatile memory 90 to the buffer memory 80 and restore the write data in the buffer memory 80. The magnetic disk device 1 can thereby continue the processing using the write data restored in the buffer memory 80.

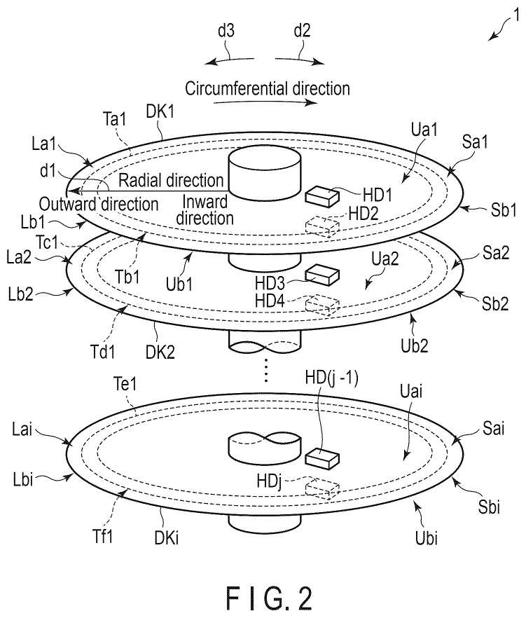

FIG. 2 is a perspective view showing parts of the magnetic disk device 1, illustrating a plurality of disks DK and a plurality of heads HD.

As shown in FIG. 2, the direction of rotation of the disks DK in the circumferential direction is referred to as a rotational direction d3. Incidentally, in the example shown in FIG. 2, the rotational direction d3 is illustrated as a counterclockwise direction, but may be an opposite (clockwise) direction. In addition, a traveling direction d2 of the heads HD relative to the disks DK is opposite to the rotational direction d3. The traveling direction d2 is the direction in which the heads HD sequentially write the data to and read data from the disks DK in the circumferential direction, i.e., the direction in which the heads HD travel with respect to the disks DK in the circumferential direction.

The magnetic disk device 1 comprises i disks, from disk DK1 through disk DKi, and j heads, from head HD1 through head HDj. In the embodiment, the number of heads HD is twice the number of disks DK (j=2×i).

The disks DK1 through DKi are provided coaxially to overlap with each other at intervals. The diameters of the disks DK1 to DKi are the same as each other. The terms “same”, “equal”, “matching”, “equivalent” and the like imply not only the meaning of being exactly the same, but also the meaning of being different to the extent that they can be regarded as substantially the same. Incidentally, the diameters of the disks DK1 to DKi may be different from each other.

Each disk DK has recording layers L on both sides. For example, the disk DK1 has a first recording layer La1 and a second recording layer Lb1 on the side opposite to the first recording layer La1. The disk DK2 has a first recording layer La2 and a second recording layer Lb2 on the side opposite to the first recording layer La2. The disk DKi has a first recording layer Lai and a second recording layer Lbi on the side opposite to the first recording layer Lai. Each first recording layer La may be referred to as a top surface or a recording surface. Each second recording layer Lb may be referred to as a back surface or recording surface.

However, each first recording layer La may be referred to as a back surface. In this case, each second recording layer Lb may be referred to as a top surface.

Each recording layer L has a user data area U and a system area S. The first recording layer La1 has a user data area Ua1 and a system area Sa1. The second recording layer Lb1 has a user data area Ub1 and a system area Sb1. The first recording layer La2 has a user data area Ua2 and a system area Sa2. The second recording layer Lb2 has a user data area Ub2 and a system area Sb2. The first recording layer Lai has a user data area Uai and a system area Sai. The second recording layer Lbi has a user data area Ubi and a system area Sbi.

A track sandwiched between double dashed lines in the figure, in the user data area Ua1 (first recording layer La1), is referred to as a track Ta1. A track located on a side opposite to the track Ta1, in the user data area Ub1 (second recording layer Lb1), is referred to as a track Tb1.

A track sandwiched between double dashed lines in the figure, in the user data area Ua2 (first recording layer La2), is referred to as a track Tc1. A track located on a side opposite to the track Tc1, in the user data area Ub2 (second recording layer Lb2), is referred to as a track Td1.

A track sandwiched between double dashed lines in the figure, in the user data area Uai (first recording layer Lai), is referred to as a track Te1. A track located on a side opposite to the track Te1, in the user data area Ubi (second recording layer Lbi), is referred to as a track Tf1.

In the embodiment, the tracks Ta1, Tb1, Tc1, Td1, Te1, and Tf1 are located on the same cylinder.

The heads HD are opposed to the disks DK. In the embodiment, one head HD is opposed to each recording layer L of the disk DK. For example, the head HD1 is opposed to the first recording layer La1 of the disk DK1, writes the data to the first recording layer La1, and reads the data from the first recording layer La1. The head HD2 is opposed to the second recording layer Lb1 of the disk DK1, writes the data to the second recording layer Lb1, and reads the data from the second recording layer Lb1.

The head HD3 is opposed to the first recording layer La2 of the disk DK2, writes the data to the first recording layer La2, and reads the data from the first recording layer La2. The head HD4 is opposed to the second recording layer Lb2 of the disk DK2, writes the data to the second recording layer Lb2, and reads the data from the second recording layer Lb2. The head HDj-1 is opposed to the first recording layer Lai of the disk DKi, writes the data to the first recording layer Lai, and reads the data from the first recording layer Lai. The head HDj is opposed to the second recording layer Lbi of the disk DKi, writes the data to the second recording layer Lbi, and reads the data from the second recording layer Lbi.

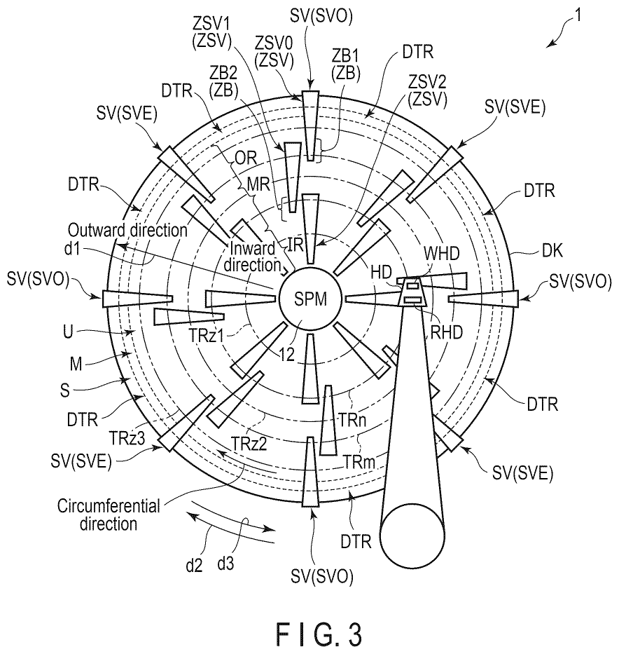

FIG. 3 is a schematic diagram showing an example of arrangement of a plurality of servo areas SV and a plurality of data areas DTR on the single disk DK according to the embodiment. As shown in FIG. 3, a direction toward the outer circumference of the disk DK in the radial direction d1 of the disk DK is referred to as an outward direction (outside), and a direction opposite to the outward direction is referred to as an inward direction (inside).

In FIG. 3, the user data area U is divided into an inner circumferential area IR located in the inward direction, an outer circumferential area OR located in the outward direction, and an intermediate circumferential area MR located between the inner circumferential area IR and the outer circumferential area OR.

The disk DK has a plurality of servo areas SV and a plurality of data areas DTR. For example, the plurality of servo areas SV may extend radially in the radial direction of the disk DK and may be discretely arranged at predetermined intervals in the circumferential direction. For example, the plurality of servo areas SV may extend linearly from the inner circumference to the outer circumference and may be discretely arranged at predetermined intervals in the circumferential direction. For example, the plurality of servo areas SV may extend in a spiral shape from the inner circumference to the outer circumference and may be discretely arranged at predetermined intervals in the circumferential direction. Alternatively, for example, the plurality of servo areas SV may be arranged in a form of islands in the radial direction and may be discretely arranged at different predetermined intervals in the circumferential direction.

In the following descriptions, one servo area SV on a particular track is often referred to as a “servo sector”. Incidentally, the “servo area SV” may be referred to as a “servo sector SV”. The servo sector includes servo data. The “arrangement of several servo data elements constituting the servo sector, and the like” may be hereinafter referred to as a “servo pattern”. Incidentally, the “servo data written in the servo sector” may be often referred to as the “servo sector”.

Each of a plurality of data areas DTR is arranged between a plurality of servo areas SV. For example, the data area DTR corresponds to the area between two continuous servo areas SV in the circumferential direction. One data area SV on a predetermined track may be hereinafter referred to as the “data sector”. Incidentally, the “data area DTR” may be referred to as a “data sector DTR”. The data sector includes user data. Incidentally, the “user data written to the data sector” may be referred to as the “data sector”. The “data sector” may be referred to as the “user data”. In addition, “a pattern composed of several data elements” may be referred to as a “data pattern”. In the example shown in FIG. 3, the data pattern of a predetermined track is composed of a plurality of servo data elements (servo sectors) and a plurality of user data elements (data sectors).

The servo area SV includes a plurality of zone servo areas ZSV and the like. Incidentally, the servo area SV may include an area including a gap (i.e., a gap between circumferential positions of two zone servo areas), an area including the servo data, the data area DTR, and the like, in addition to the zone servo areas ZSV. The plurality of zone servo areas ZSV are discretely arranged in the radial direction d1. Each of the plurality of zone servo areas ZSV extends in the radial direction d1.

One zone servo area (servo area) ZSV on a predetermined track may be referred to as a “zone servo sector” or a “servo sector”. Incidentally, the “zone servo area (servo area) ZSV” may be referred to as a “zone servo sector ZSV” or a “servo sector ZSV”. The “servo data written to the zone servo sector” may be referred to as a “zone servo sector” or a “servo sector”. The “arrangement of several servo data elements constituting the zone servo sector, and the like” may also be hereinafter referred to as a “zone servo pattern” or a “servo pattern”. One servo area SV on a predetermined track may also be hereinafter referred to as a “zone pattern sector”.

Incidentally, the “servo area SV” may be referred to as the “zone pattern sector”. The “at least one data element and the like written to the zone pattern sector” may be referred to as the “zone pattern sector”. The zone pattern sector includes at least one zone servo sector. The “data pattern of the zone pattern sector” may be hereinafter referred to as a “zone data pattern”.

In the example shown in FIG. 3, the servo areas SV include zone servo areas ZSV0, ZSV1, and ZSV2. The zone servo areas ZSV0, ZSV1, and ZSV2 are arranged in a staggered pattern in the radial direction. The zone servo areas ZSV0, ZSV1, and ZSV2 may be arranged in a staircase pattern in the radial direction.

The zone servo area ZSV2 is located on an inner circumferential side than the zone servo area ZSV1. The zone servo area ZSV0 is located on an outer circumferential side than the zone servo area ZSV1. For example, the zone servo area ZSV2 is arranged to extend from the inner circumferential area IR to the intermediate circumferential area MR, the zone servo area ZSV1 is arranged to extend from the inner circumferential area IR to the outer circumferential area OR, and the zone servo area ZSV0 is arranged to extend from the intermediate circumferential area MR to the outer circumferential area OR. In the following descriptions, a predetermined radial area in which the plurality of zone servo areas ZSV are arranged in the circumferential direction, in a predetermined servo area SV, may be referred to as a zone servo boundary area, double servo area, or double zone servo area ZB.

In the example shown in FIG. 3, the main servo areas SVO and the sub-servo areas SVE are alternately arranged at intervals in the circumferential direction. For example, one sub-servo area SVE is arranged between two main servo areas SVO that are continuously aligned at an interval in the circumferential direction. In other words, one sub-servo area SVE is arranged between two main servo areas SVO that are continuously aligned at an interval in the circumferential direction. For example, when sequentially continuous numbers are assigned to all the servo areas SV of the disk DK, the main servo areas SVO correspond to the odd-numbered servo areas SV, and the sub-servo areas SVE correspond to the even-numbered servo areas SV. Incidentally, two or more sub-servo areas SVE may be arranged between two main servo areas SVO that are continuously arranged at an interval, in the circumferential direction.

The main servo areas SVO and the sub-servo areas SVE may be composed of, for example, only servo areas where the servo data is read and demodulated as a whole (hereinafter often referred to as normal servo areas). In the following descriptions, “reading and demodulating the servo data” may be referred to as “servo-reading”. The main servo areas SVO and the sub-servo areas SVE may be composed of, for example, the normal servo areas, and servo areas (hereinafter often referred to as short servo areas) where servo-reading is executed in a smaller circumferential range of the servo data than a circumferential range of the servo data which is servo-read in the normal servo areas.

A media cache M is allocated to the disk DK. However, the media cache M may not be arranged on the disk DK.

By using the above-described plurality of servo data elements, for example, the positioning error of the head HD (for example, the write head WHD) can be derived.

In the embodiment, it has been described that the number of zones of the disk DK is three, but the number of zones of the disk DK can be variously changed. The number of zones of the disk DK may be thirty to forty. In addition, each zone includes a plurality of bands. For example, each zone includes several hundreds of bands.

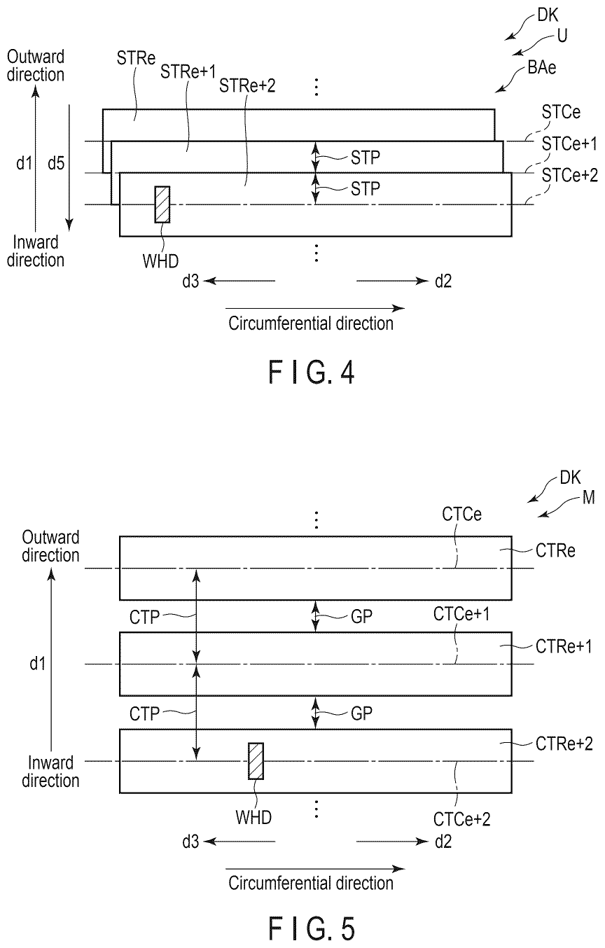

FIG. 4 is a schematic diagram showing three tracks STR of the user data area U where the shingled magnetic recording processing is executed for the disk DK shown in FIG. 3, and the write head WHD. The user data area U is a shingled magnetic recording area. Sequentially writing the data in band units in the user data area U is permitted, i.e., shingled magnetic recording is permitted.

As shown in FIG. 4, the write head WHD can sequentially write the data to the disk DK in the traveling direction d2. The read head RHD shown in FIG. 3 can also sequentially read the data written to the disk DK in the traveling direction d2.

In the direction parallel to the radial direction d1, the direction of sequentially executing the shingled magnetic recording for a plurality of tracks STR that are a plurality of data tracks, i.e., the direction of making a track STR to which the data is be next written overlap with a track STR to which the data has been previously written, in the radial direction d1, is referred to as an overwrite direction or a recording progress direction. In a band BAe shown in FIG. 4, an overwrite direction d5 is an inward direction, but the overwrite direction may be an outward direction.

For example, an overwrite direction applied to a plurality of bands BA (a plurality of zones Z) located on an outer circumference side than a specific radial position and an overwrite direction applied to a plurality of bands BA (a plurality of zones Z) located on an inner circumferential side than the specific radial position may be opposite to each other.

The band BAe includes a plurality of tracks STR including tracks STRe, STRe+1, and STRe+2. The tracks STRe, STRe+1, and STRe+2 are sequentially overwritten in the overwrite direction d5 in the order described above. The track STRe among the tracks STRe, STRe+1, and STRe+2 corresponds to the track where data is first written, and the track STRe+2 corresponds to the track where data is last written.

The track STRe has a track center STCe at the center of the radial direction d1 when no other tracks are overwritten. The track STRe+1 has a track center STCe+1 at the center of the radial direction d1 when no other tracks are overwritten. The track STRe+2 has a track center STCe+2 at the center of the radial direction d1 when no other tracks are overwritten.

In the example shown in FIG. 4, the data is written to the tracks STRe, STRe+1, and STRe+2 at a pitch (shingled magnetic recording track pitch) STP. The track center STCe of the track STRe and the track center STCe+1 of the track STRe+1 are separated from each other at a pitch STP in the radial direction d1. The track center STCe+1 of the track STRe+1 and the track center STCe+2 of the track STRe+2 are separated from each other at a pitch STP in the radial direction d1. The data may be written to the tracks STRe to STRe+2 at different pitches.

A width in the radial direction d1 of the area of the track STRe where the track STRe+1 is not overwritten and a width in the radial direction d1 of the area of the track STRe+1 where the track STRe+2 is not overwritten are the same as each other. Incidentally, the width in the radial direction d1 of the area of the track STRe where the track STRe+1 is not overwritten and the width in the radial direction d1 of the area of the track STRe+1 where the track STRe+2 is not overwritten may be different from each other.

In FIG. 4, each track STR has a rectangular shape for convenience of descriptions but, in reality, each track STR is curved along the circumferential direction. In addition, each track STR may have a wave shape extending in the circumferential direction while varying in the radial direction d1. Incidentally, three tracks STRs are overwritten in FIG. 4, but two tracks STR may be overwritten or more three tracks STR may be overwritten.

The write processing unit 62 can select the shingled magnetic recording system of overwriting the data on a plurality of tracks STR in the overwrite direction d5 and cause the write head WHD to write the data to each of the bands BA. In the example shown in FIG. 4, the write processing unit 62 sequentially executes the shingled magnetic recording of the tracks STRe to STRe+2 in the band BAe at the pitch STP in the inward direction (overwrite direction d5). Since the user data area U is the area where the data is written in the shingled magnetic recording, the recording density of the user data area U can be improved.

The write processing unit 62 writes the data to the track STRe+1 at the pitch STP in the inward direction of the track STRe and overwrites the track STRe+1 on an inner circumferential part of the track STRe. The write processing unit 62 writes the data to the track STRe+2 at the pitch STP in the inward direction of the track STRe+1 and overwrites the track STRe+2 on an inner circumferential part of the track STRe+1.

FIG. 5 is a schematic diagram showing three tracks CTR of the media cache M where the conventional magnetic recording processing of the disk DK shown in FIG. 3 is executed, and the write head WHD. The media cache M and the system area S shown in FIG. 3 are the conventional magnetic recording areas. In the media cache M and the system area S, randomly writing the data is permitted, i.e., conventional magnetic recording is permitted.

As shown in FIG. 5, the media cache M includes a plurality of tracks CTR including tracks CTRe, CTRe+1, and CTRe+2. Each of a plurality of tracks CTR is a data track. For example, widths (track widths) in the radial direction d1 of the tracks CTRe, CTRe+1, and CTRe+2 are the same as each other. Incidentally, the track widths of the tracks CTRe to CTRe+2 may be different from each other.

The track CTRe has a track center CTCe at the center of the radial direction d1, the track CTRe+1 has a track center CTCe+1 at the center of the radial direction d1, and the track CTRe+2 has a track center CTCe+2 at the center of the radial direction d1. In the example shown in FIG. 5, the tracks CTRe, CTRe+1, and CTRe+2 are written at the pitch (conventional magnetic recording track pitch) CTP. The track center CTCe of the track CTRe and the track center CTCe+1 of the track CTRe+1 are separated from each other at the pitch CTP. The track center CTCe+1 of the track CTRe+1 and the track center CTCe+2 of the track CTRe+2 are separated from each other at the pitch CTP.

The track CTRe and the track CTRe+1 are separated from each other at a gap GP. The track CTRe+1 and the track CTRe+2 are separated from each other at the gap GP. Incidentally, the data may be written to the tracks CTRe to CTRe+2 at different pitches. In FIG. 5, each track CTR has a rectangular shape for convenience of descriptions but, in reality, each track CTR is curved along the circumferential direction. In addition, each track CTR may have a wave shape extending in the circumferential direction while varying in the radial direction d1.

The write processing unit 62 can execute the write processing by selecting the conventional magnetic recording of writing the data to a plurality of tracks CTR spaced apart in the radial direction d1 of the disk DK. In the example shown in FIG. 5, the write processing unit 62 positions the write head WHD at the track center CTCe in a predetermined area of the disk DK and executes the conventional magnetic recording in a predetermined sector of the track CTRe or the track CTRe.

The write processing unit 62 positions the write head WHD at the track center CTCe+1, which is separated from the track center CTCe of the track CTRe in the inward direction by the pitch CTP, and executes the conventional magnetic recording in a predetermined sector of the track CTRe+1 or the track CTRe+1. The write processing unit 62 positions the write head WHD at the track center CTCe+2, which is separated from the track center CTCe+1 of the track CTRe+1 in the inward direction by the pitch CTP, and executes the conventional magnetic recording in a predetermined sector of the track CTRe+2 or the track CTRe+2.

The write processing unit 62 may sequentially execute the conventional magnetic recording in the tracks CTRe, CTRe+1, and CTRe+2, in a predetermined area of the disk DK, or randomly execute the conventional magnetic recording in a predetermined sector of the track CTRe, a predetermined sector of the track CTRe+1, and a predetermined sector of the track CTRe+2.

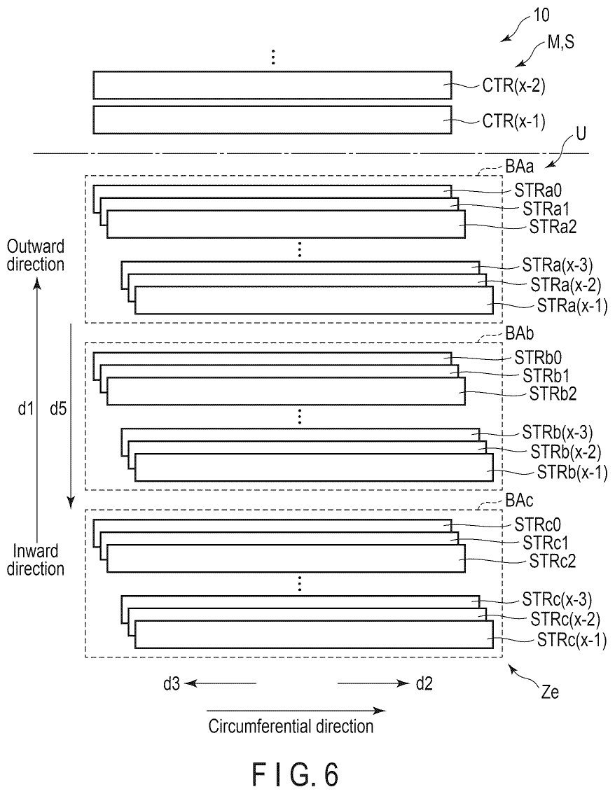

FIG. 6 is a schematic diagram showing an example of the data write processing on the disk DK. Each of the tracks STR and CTR is a data track. As shown in FIG. 6, the user data area U includes bands BAa, BAb, and BAc. The bands BAa, BAb, and BAc belong to the same zone Ze. In the zone Ze, the bands BAa, BAb, and BAc are intermittently arranged in the overwrite direction d5 in the order of these descriptions.

The bands BAa and BAb are adjacent to each other in the radial direction d1, and the bands BAb and BAc are adjacent to each other in the radial direction d1.

The band BAa includes x tracks such as tracks STRa0, STRa1, STRa2, . . . , STRa(x−3), STRa(x−2), and STRa(x−1). The tracks STRa0 to STRa(x−1) are subjected to the shingled magnetic recording in the overwrite direction d5 in the order of these descriptions. In the band BAa, the track STRa0 corresponds to a first track where the data is first written, and the track STRa(x−1) corresponds to the last track where the data is last written.

The band BAb includes x tracks such as tracks STRb0, STRb1, STRb2, . . . , STRb(x−3), STRb(x−2), and STRb(x−1). The tracks STRb0 to STRb(x−1) are subjected to the shingled magnetic recording in the overwrite direction d5 in the order of these descriptions. In the band BAb, the track STRb0 corresponds to a first track where the data is first written, and the track STRb(x−1) corresponds to the last track where the data is last written.

The band BAc includes x tracks such as tracks STRc0, STRc1, STRc2, . . . , STRc(x−3), STRc(x−2), and STRc(x−1). The tracks STRc0 to STRc(x−1) are subjected to the shingled magnetic recording in the overwrite direction d5 in the order of these descriptions. In the band BAc, the track STRc0 corresponds to a first track where the data is first written, and the track STRc(x−1) corresponds to the last track where the data is last written.

The number of the tracks STR included in each of the bands BA belonging to the same zone Z is the same. For example, the number of the tracks STR included in each of the bands BA belonging to the zone Ze is the same. In other words, the number of the tracks STR included in the band BA is fixed for each zone Z. In this example, the number of tracks STR in each of the bands BA belonging to the zone Ze is x.

FIG. 6 shows tracks CTR(x−2) and CTR(x−1). In FIG. 6, the tracks CTR(x−2) and CTR(x−1) are subjected to the conventional magnetic recording in the media cache M or the system area S. The tracks CTR(x−2) and CTR(x−1) are adjacent to each other in the radial direction d1.

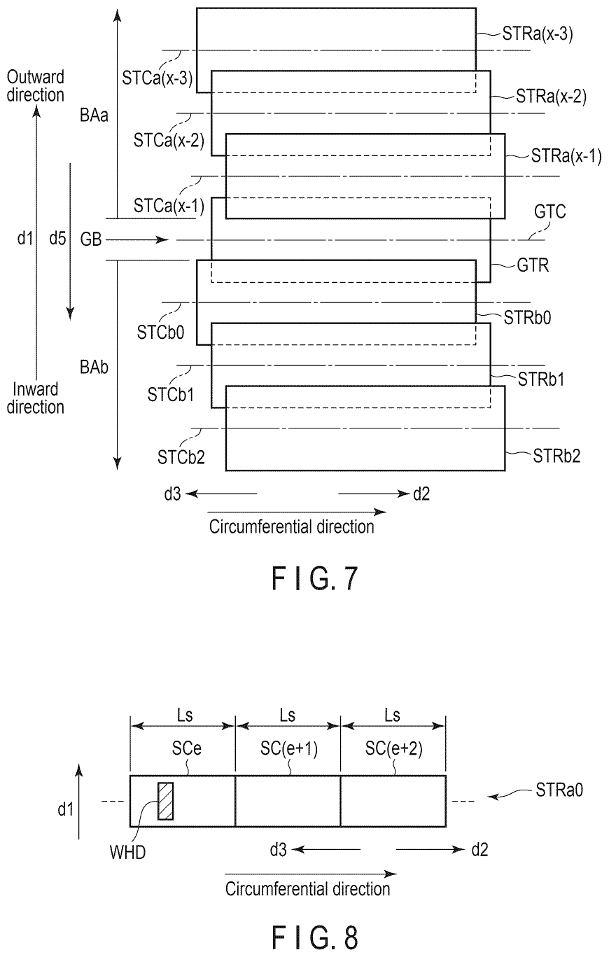

FIG. 7 is a schematic diagram showing two bands BAa and BAb and one guard band GB of the user data area U shown in FIG. 6. As shown in FIG. 7, in the shingled magnetic recording, unlike the conventional magnetic recording, the MPU 60 manages a track group of the user data area U in units referred to as bands, with the feature of overwriting the data to a part of the track STR.

A guard band GB is generally provided between adjacent bands BA in the radial direction d1. The guard band GB includes a guard track GTR. Unlike the embodiment, the guard band GB may include a plurality of guard tracks GTR. The guard band GB has a role of suppressing the interference between the adjacent bands BA. The shingled magnetic recording can be executed in a unit of one band BA by the guard band GB. In addition, the ranges (bands BA) where the data is sequentially written can be separated by the guard band GB.

For example, the track center STCa(x−3) of the track STRa(x−3), the track center STCa(x−2) of the track STRa(x−2), the track center STCa(x−1) of the track STRa(x−1), the track center GTC of the guard track GTR, the track center STCb0 of the track STRb0, the track center STCb1 of the track STRb1, and the track center STCb2 of the track STRb2, are located at equal pitch in the overwrite direction d5.

The recording capacity of each band BA in the user data area U is usually predetermined based on the specifications required by the user except for the guard band GB. The MPU 60 can record the same capacity of data in each of the bands BA. In general, the recording capacity of each band BA is 128 MiB or 256 MiB.

FIG. 8 is a schematic diagram showing three sectors SCe, SC(e+1), and SC(e+2) of one track STRa0 of the band BAa shown in FIG. 6. As shown in FIG. 8, each track STR includes a plurality of sectors SC. The track STRa1 includes a plurality of sectors SC including sectors SCe, SC(e+1), and SC(e+2). The number of the sectors SC included in each of the tracks STR belonging to the same zone Z is the same. In the embodiment, the number of sectors SC included in each of the tracks STR belonging to the zone Ze is y.

Each of the sectors SC has a length Ls in the circumferential direction of the disk DK. Each sector SC may be a split sector that is divided by the servo sector SV. In this case, the length of the sector SC does not need to be Ls.

The write head WHD is a magnetic head for energy-assisted recording that executes energy assisted magnetic recording (EAMR). In the embodiment, the write head WHD is configured to use energy other than the magnetic energy, but the write head WHD may also be a magnetic head that is not configured to execute the energy assisted magnetic recording.

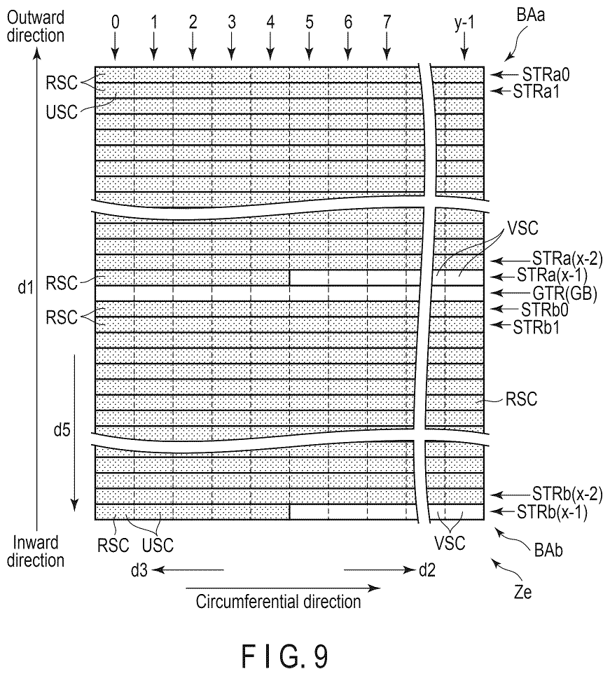

FIG. 9 is a schematic diagram showing the two bands BAa and BAb and one guard band GB shown in FIG. 7, illustrating the plurality of target sectors RSC and the plurality of unused sectors VSC.

In FIG. 9, each track STR has a rectangular shape for convenience of description but, in reality, each track STR is curved along the circumferential direction. In addition, a plurality of tracks STR are aligned in the overwrite direction d5 without overlapping but, in reality, the plurality of tracks STR are aligned in the overwrite direction d5 while overlapping. In the figure, the target sector RSC is marked with a dot pattern. Unused sectors VSC are represented by a solid color.

As shown in FIG. 9, the band number of the band BAa is “a” and the band number of the band BAb is “b”. The track numbers of the respective bands BA are set to “0” to “x−1”. The sector numbers of the respective tracks STR are set to “0” to “y−1”. In the following descriptions, the sector SC of each band BA may be identified by the following code “SC (track number or sector number)”.

In the embodiment, the band BAa is a band adjacent to a band BAb, and is a band located above the band BAb in the overwrite direction d5.

Each track STR of the band BAa includes G target sectors RSC (one or more target sectors RSC) on which valid data is written. For example, the track STRa0 includes y target sectors RSC (G=y). All the sectors SC of the track STRa0 are the target sectors RSC. The track STRa(x−1) includes five target sectors RSC (G=5). The remaining sectors SC of the track STRa(x−1) are unused sectors VSC where valid data is not written.

Based on the above, the number of target sectors RSC on the track STRa0 is different from the number of target sectors RSC on the track STRa(x−1).

In each of the bands BA of the zone Ze, all the sectors SC of x−1 tracks STR from number 0 to number x−2 are the target sectors RSC where valid data is written, and are the record sectors USC. On the x−1-th track STR of each band BA of the zone Ze, five sectors SC from number 0 to number 4 are the target sectors RSC, and are the record sectors USC. In contrast, on the x−1-th track STR, remaining sectors SC from number 5 to number y−1 are the unused sectors VSC where valid data is not written.

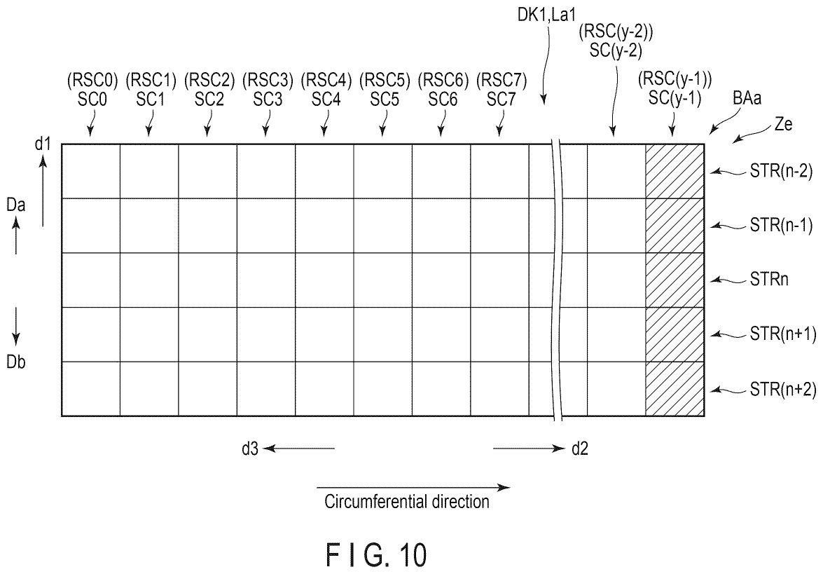

FIG. 10 is a schematic diagram showing five tracks STR(n−2), STR(n−1), STR(n), STR(n+1), and STR(n+2) of the recording layer La1 of the disk DK1 shown in FIG. 2. In FIG. 10, each track STR has a rectangular shape but, in reality, each track STR is curved along the circumferential direction.

As shown in FIG. 10, the recording layer La1 includes five track STRs (n−2) to (n+2), which are five data tracks continuous in the radial direction d1. Each of the tracks STR includes a plurality of sectors SC0 to SC(y−1). In the embodiment, the plurality of sectors SC0 to SC(y−1) of the tracks STR(n−2) to STR(n+2) are the plurality of target sectors RSC to which data is written.

In this example, the tracks STR(n−1) to STR(n+1) will be focused. In the following descriptions, the track STR(n−1) is referred to as a first track STR(n−1), the track STRn is referred to as a second track STRn, and the track STR(n+1) is referred to as a third track STR(n+1).

The second track STRn is located in the second direction Db as viewed from the first track STR(n−1), in the direction parallel to the radial direction d1. The third track STR(n+1) is located in the second direction Db as viewed from the second track STRn.

The write processing unit 62 can select the shingled magnetic recording of writing data to the first track STR(n−1), the second track STRn, and the third track STR(n+1) in order while overlapping in the second direction Db, and execute the write processing.

The write processing unit 62 writes the first user data to the plurality of target sectors RSC of the first track STR(n−1) during a first write period, refers to the target sectors as the plurality of user data sectors, writes the first conventional parity to the remaining one or more target sectors RSC of the first track STR(n−1), and refers to the target sectors as one or more parity sectors. In the first track STR(n−1) of the embodiment, each of the plurality of target sectors RSC0 to RSC(y−2) is a user data sector, and the target sector RSC(y−1) is a parity sector.

The write processing unit 62 writes the second user data to the plurality of target sectors RSC of the second track STRn during a second write period following first write period, refers to the target sectors as the plurality of user data sectors, writes the second conventional parity to the remaining one or more target sectors RSC of the second track STRn, and refers to the target sectors as one or more parity sectors. In the second track STRn of the embodiment, each of the plurality of target sectors RSC0 to RSC(y−2) is a user data sector, and the target sector RSC(y−1) is a parity sector.

The write processing unit 62 writes the third user data to the plurality of target sectors RSC of the third track STR(n+1) during a third write period following the second write period, refers to the target sectors as the plurality of user data sectors, writes the third conventional parity to the remaining one or more target sectors RSC of the third track STR(n+1), and refers to the target sectors as one or more parity sectors. In the third track STR(n+1) of the embodiment, each of the plurality of target sectors RSC0 to RSC(y−2) is a user data sector, and the target sector RSC(y−1) is a parity sector.

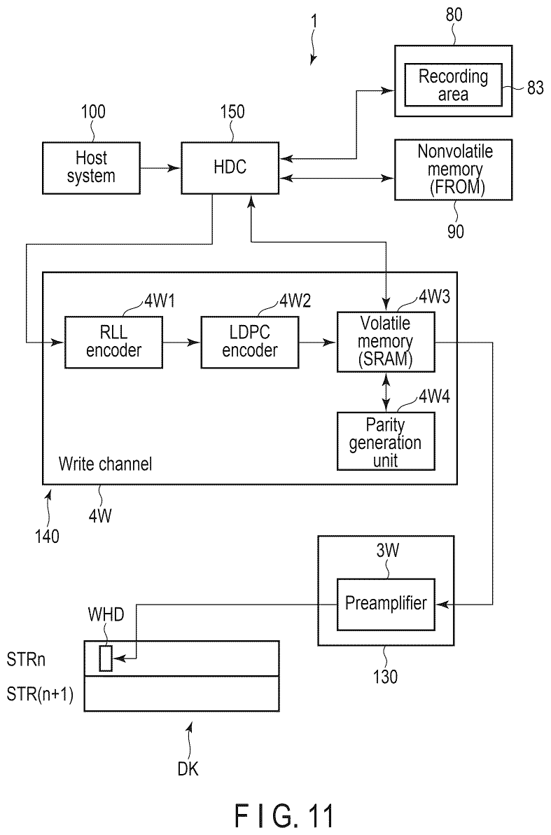

FIG. 11 is a block diagram showing a configuration of a part of the magnetic disk device 1 and showing a configuration of a write channel 4W, and the like.

As shown in FIG. 11, the write channel 4W of the above-described R/W channel 140 comprises a run length limited (RLL) encoder 4W1, a low density parity check (LDPC) encoder 4W2, a volatile memory 4W3, and a parity generation unit 4W4.

The RLL encoder 4W1 and the LDPC encoder 4W2 function as data processors that process the received data. In the embodiment, the above-described data processors execute processing of encoding the received data. The received data is RLL-encoded by the RLL encoder 4W1 and LDPC-encoded by the LDPC encoder 4W2. The parity generation unit 4 W4 is configured to execute XOR operations on the data processed by the above-described data processors (RLL encoder 4W1 and LDPC encoder 4W2).

The data processed by the above-described data processors and the data that is XOR-processed by the parity generation unit 4W4 is written to the volatile memory 4W3 provided in the write channel 4W. The volatile memory 4W3 is a RAM.

The parity generation unit 4W4 can generate a first conventional parity and a first potential parity for error correction of first corrupted data of one or more corrupted target sectors of the first track STR(n−1), based on the first user data to be written to the first track STR(n−1). The ability of the first potential parity to correct errors in the first corrupted data is higher than the ability of the first conventional parity to correct errors in the first corrupted data.

The parity generation unit 4W4 can generate a second conventional parity and a second potential parity for error correction of second corrupted data of one or more corrupted target sectors of the second track STRn, based on the second user data to be written to the second track STRn. The ability of the second potential parity to correct errors in the second corrupted data is higher than the ability of the second conventional parity to correct errors in the second corrupted data.

The parity generation unit 4W4 can generate a third conventional parity and a third potential parity for error correction of third corrupted data of one or more corrupted target sectors of the third track STR(n+1), based on the third user data to be written to the third track STR(n+1). The ability of the third potential parity to correct errors in the third corrupted data is higher than the ability of the third conventional parity to correct errors in the third corrupted data.

The data length of the first potential parity is longer than the data length of the first conventional parity written to one or more parity sectors of the first track STR(n−1), and is shorter than the data length of the first user data written to the plurality of user data sectors of the first track STR(n−1).

The data length of the second potential parity is longer than the data length of the second conventional parity written to one or more parity sectors of the second track STRn, and is shorter than the data length of the second user data written to the plurality of user data sectors of the second track STRn.

The data length of the third potential parity is longer than the data length of the third conventional parity written to one or more parity sectors of the third track STR(n+1), and is shorter than the data length of the third user data written to the plurality of user data sectors of the third track STR(n+1).

The data processed by the above-described data processor and the data XOR-processed by the parity generation unit 4W4 are temporarily stored in the volatile memory 4W3. For example, the user data and the conventional parity, among the data in the volatile memory 4W3, are transferred to the volatile memory 70, and the potential parity is stored in the recording area 83. The storage processing unit 65 can store the potential parity in the buffer memory 80 in the order of generating the potential parity. For example, the storage processing unit 65 can store the first potential parity in the buffer memory 80, then store the second potential parity in the buffer memory 80, and then store the third potential parity in the buffer memory 80.

When the data is written to the second track STRn, the second user data and the second conventional parity are retransferred from the volatile memory 70 to the volatile memory 4W3, and transmitted to the write head WHD via the preamplifier 3W of the head amplifier IC 130, and writing to the second track STRn is executed. Incidentally, the transfer destination of the user data and the conventional parity is not limited to the volatile memory 70, but may be a storage medium or storage area other than volatile memory 70.

Alternatively, the user data and conventional parity may not be transferred from the volatile memory 4W3 to the volatile memory 70, but the data may be transmitted to the write head WHD via the preamplifier 3W.

Next, a case where it is assumed that the magnetic disk device 1 does not comprise the function of executing the track-based error correction for the data of the track STR will be compared with a case where the magnetic disk device 1 comprises the function of executing the track-based error correction.

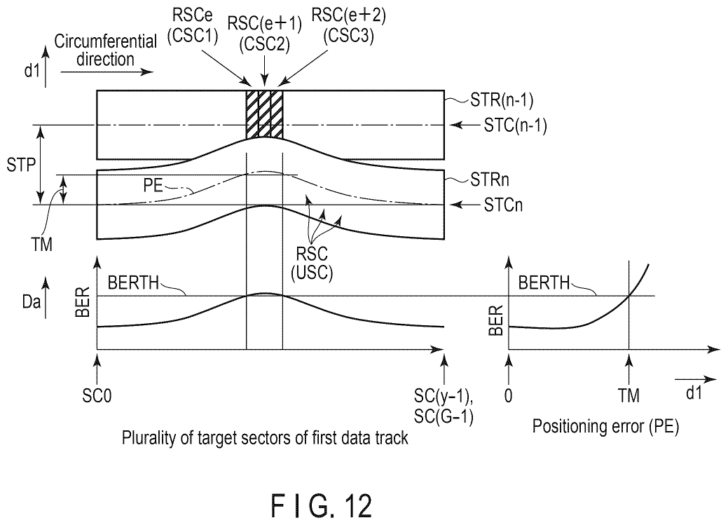

FIG. 12 is a schematic diagram showing an example of the first track STR(n−1) and the second track STRn in a case where it is assumed that the magnetic disk device 1 does not comprise a function of executing the track-based error correction of the data on the track STR, illustrating the write processing for the first track STR(n−1) and the second track STRn, illustrating a state in which the write processing for the second track STRn is continued until the error correction in each sector for the first track STR(n−1) reaches its limit, and illustrating each of the change in a bit error rate (BER) for the first track STR(n−1) and the change in BER for the positioning error PE in graph form.

In the descriptions made with reference to FIG. 12, it is assumed that the magnetic disk device 1 does not comprise the error correction unit 64 shown in FIG. 1. In addition, in FIG. 12 as well, the first track STR(n−1) and the like are drawn by assuming the circumferential direction to be linear, for convenience of descriptions.

As shown in FIG. 12, the write processing for the first track STR(n−1) is executed ideally without any positioning error PE (PE≈0 or PE=0). If the magnetic disk device 1 is affected by external vibration or the like during the write processing, a positioning error PE occurs when positioning the write head WHD. The positioning error PE is the amount of deviation from the target position of the write head WHD in the radial direction d1. By setting a track margin TM, the allowable range in which it is guaranteed that data on adjacent tracks can be read can be determined.

For example, if the write processing is executed on the second track STRn and if the target sectors RSCe, RSC(e+1), and RSC(e+2) of the first track STR(n−1) are adjacent to the write head WHD in the radial direction d1 during the period when the positioning error PE exceeds the track margin TM, it is determined (predicted) that the data in the target sectors RSCe, RSC(e+1), and RSC(e+2) of the first track STR0 are corrupted. Although a lower BER of the data is desirable, the BER of the data of the target sectors RSCe, RSC(e+1), and RSC(e+2) of the first track STR(n−1) exceeds a threshold value BERTH. Incidentally, as understood from the graph on the right side of FIG. 12, as the positioning error PE becomes greater, the adverse effect of adjacent track interference (ATI) becomes greater and the BER of the data on the first track STR(n−1), which is excessively adversely affected by ATI, becomes excessively high.

For this reason, the target sectors RSCe, RSC(e+1), and RSC(e+2) among the plurality of target sectors RSC of the first track STR(n−1) are determined to be corrupted target sectors CSC1, CSC2, and CSC3, respectively. This matter may lead to situations where the quality of the signals obtained by reading the data in the corrupted target sectors CSC1, CSC2, and CSC3 are deteriorated or the data in the corrupted target sectors CSC1, CSC2, and CSC3 is erased.

In the example described with reference to FIG. 12, the magnetic disk device 1 does not comprise a function of executing track-based error correction for the data on the track TR. For this reason, the target sectors RSCe, RSC(e+1), and RSC(e+2) remain the corrupted target sectors CSC1, CSC2, and CSC3, respectively.

In FIG. 12, it has been described that all the target sectors RSC of the track STR have a common track margin TM. However, the above-described setting of the track margin TM is just an example, and the track margin TM may be different for each target sector RSC.

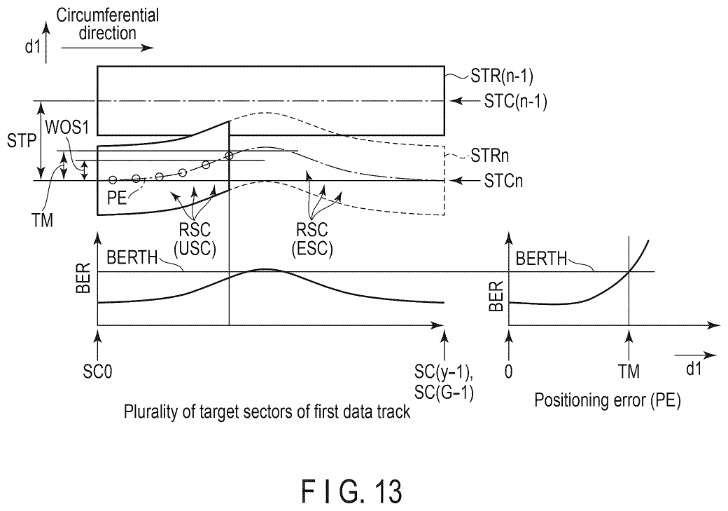

FIG. 13 is a schematic diagram showing an example of the first track STR(n−1) and the second track STRn in a case where it is assumed that the magnetic disk device 1 does not comprise a function of executing the track-based error correction for the data of the track STR, illustrating the write processing for the first track STR(n−1) and the second track STRn, illustrating a state in which a determination value is set to a write-off track slice WOS1 smaller (more severe) than the track margin TM and which the write processing for the second track STRn is ended when it is detected that the positioning error PE becomes greater than or equal to the write-off track slice WOS1, and illustrating each of the change in BER for the first track STR(n−1) and the change in BER for the positioning error PE in graph form.

In FIG. 13 as well, the first track STR(n−1) and the like are drawn by assuming the circumferential direction to be linear, for convenience of descriptions. In the descriptions made with reference to FIG. 13, it is assumed that the magnetic disk device 1 does not comprise the error correction unit 64 shown in FIG. 1.

As shown in FIG. 13, the write processing for the first track STR(n−1) is executed ideally without any positioning error PE (PE≈0 or PE=0). In order to prevent or suppress the write processing in a state where the positioning error PE exceeds the track margin TM, the magnetic disk device 1 has a write-off track slice WOS1.

When it is determined that the positioning error PE has exceeded the write-off track slice WOS1 during the period when the data is being written to the second track STRn, writing the data to the second track STRn can be suspended. The remaining target sectors RSC for which data writing has been postponed, among the plurality of target sectors RSC of the second track STRn, become empty sectors ESC where no data is written. The occurrence of the corrupted target sectors CSC on the first track STR(n−1) can be prevented by avoiding the situation in which the positioning error PE exceeds the track margin TM.

Incidentally, the track STR has a servo sector in addition to the sector SC that is the data sector. In the track STR, data sectors and servo sectors are generally arranged alternately. The write head WHD can derive the positioning error PE together with the servo sector. Therefore, the positioning error PE is generally information which can be obtained intermittently.

In order to prevent PE from becoming greater than TM, the write-off track slice WOS1 needs to be set such that WOS1≤TM. In order to avoid the situation where PE becomes greater than TM, it is desirable to set the write-off track slice WOS1 such that WOS1<TM. Thus, the write processing for the second track STRn can be ended before the positioning error PE exceeds the track margin TM, and the situation in which the quality of the data on the first track STR(n−1) is deteriorated can be avoided.

However, it needs to be noted that the write processing can be ended more easily as the write-off track slice WOS1 is set to be smaller, which leads to a decrease in the write performance of the magnetic disk device 1. Incidentally, if the write processing for the second track STRn is suspended, in the magnetic disk device 1 that does not comprise the function of executing the track-based error correction, a write retry processing of resuming the write processing for the second track STRn after awaiting the rotation of the disk DK until PE≤WOS1, is resumed. Since the empty sector ESC of the second track STRn can be changed to a record sector USC, in the write retry processing, the situation in which the utilization efficiency of the second track STRn remains low is avoided.

In FIG. 13, it has been described that all the target sectors RSC of the track STR have a common write-off track slice WOS1. However, the above-described setting of the write-off track slice WOS1 is an example, and the write-off track slice WOS1 may be different for each target sector RSC.

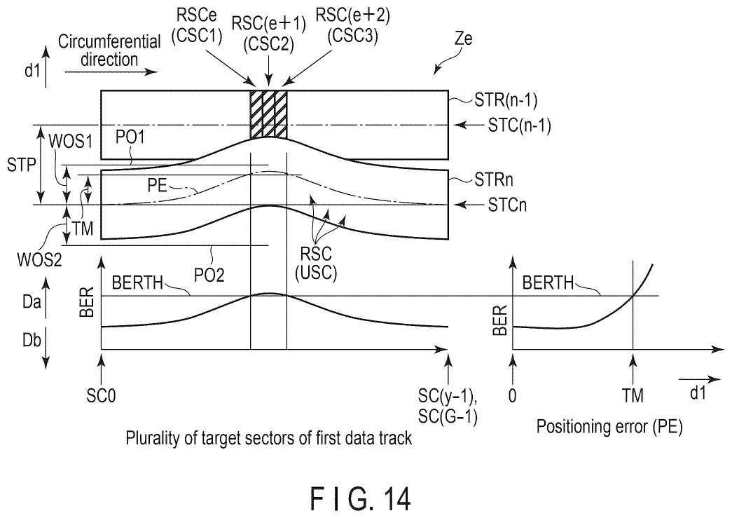

FIG. 14 is a schematic diagram showing an example of the first track STR(n−1) and the second track STRn of the magnetic disk device 1 that comprises a function of executing the track-based error correction for the data of the track STR, illustrating the write processing for the first track STR(n−1) and the second track STRn, illustrating a state in which a determination value is set to a write-off track slice WOS1 greater (more loose) than the track margin TM and which the write processing for the second track STRn is continued even after track-based error correction for the first track STR(n−1) reaches a limit, and illustrating each of the change in BER for the first track STR(n−1) and the change in BER for the positioning error PE in graph form.

In FIG. 14 as well, the first track STR(n−1) and the like are drawn by assuming the circumferential direction to be linear, for convenience of descriptions.

As shown in FIG. 14, the write processing for the first track STR(n−1) is executed ideally without any positioning error PE (PE≈0 or PE=0).

The magnetic disk device 1 comprises a error correction unit 64. When a corrupted target sector CSC occurs in the track STR, the read processing unit 63 can detect, together with the head amplifier IC 130, that the corrupted target sector CSC has occurred in the track STR, and the error correction unit 64 can execute the conventional error correction processing to recover the data of the corrupted target sector CSC. For example, if a corrupted target sector CSC occurs in the first track STR(n−1), the error correction unit 64 recovers the data of the corrupted target sector CSC, based on the first user data of the plurality of target sectors RSC and the parity of the parity sector on the first track STR(n−1).

The above parity sector is generated based on the data of the plurality of target sectors RSC of the first track STR(n−1), and can be provided in part of the plurality of target sectors RSC of the first track STR(n−1). For example, target sector RSC(y−1) of the first track STR(n−1) can be used as the parity sector. However, the above parity sector may be provided in track STR or CTR other than the first track STR(n−1). Alternatively, the above parity sectors may be provided in the memory other than the disk DK (for example, nonvolatile memory 90).

As described above, even if a corrupted target sector CSC occurs in the first track STR(n−1), the error correction unit 64 can execute the conventional error correction processing to recover the data of the corrupted target sector CSC. The occurrence of the corrupted target sector CSC in the first track STR(n−1) can be therefore allowed. In the magnetic disk device 1 comprising the error correction unit 64, the write-off track slice WOS1 can be set such that WOS1≥TM.

Incidentally, even if the error correction unit 64 executes the track-based conventional error correction, errors in the corrupted data cannot be corrected in some cases. In such cases, the error correction unit 64 can correct the corrupted data by executing track-based potential error correction.

Since the potential parity and the like are used for the potential error correction, the corresponding potential parity needs to be stored in the buffer memory 80 if there is a plan to execute the potential error correction. In this case, it is desirable to be able to efficiently record the potential parity.

Therefore, the conventional correction limit prediction unit 66 generates first prediction information that is the information for predicting whether the first conventional error correction of the first corrupted data on the first track STR(n−1) using the first conventional parity of the error correction unit 64 reaches its limit after the second user data and the second conventional parity are written to the second track STRn.

If the first prediction information is normal information for predicting that the first conventional error correction may not reach its limit, the storage processing unit 65 can maintain a recording area where the potential parity is stored, in the buffer memory 80, store the second potential parity in the first recording area where the first potential parity is stored, in the buffer memory 80, and overwrite the second potential parity to the first recording area. If there is no need to execute the potential error correction on the data on the first track STR(n−1) using the first potential parity and the like, the first potential parity can be deleted in the buffer memory 80 and the first potential parity can be updated to the second potential parity in the buffer memory 80. This can contribute to the efficient recording of the potential parity.

In contrast, if the first prediction information is replaced with abnormal information for predicting that the first conventional error correction may reach its limit, the storage processing unit 65 can change the recording area where the potential parity is stored, in the buffer memory 80, leave the first potential parity in the first recording area, and store the second potential parity in the second recording area which is different from the first recording area, in the buffer memory. If it is necessary to execute the potential error correction on the data in the first track STR(n−1) using the first potential parity and the like, the first potential parity can be left in the buffer memory 80.

As shown in FIG. 10 and FIG. 14, the conventional correction limit prediction unit 66 generates second prediction information that is the information for predicting whether the second conventional error correction of the second corrupted data on the second track STRn using the second conventional parity of the error correction unit 64 may reach its limit after the second user data and the second conventional parity are written to the second track STRn.

If the second prediction information is normal information for predicting that the second conventional error correction may not reach its limit, the storage processing unit 65 can maintain a recording area where the potential parity is stored, in the buffer memory 80, store the third potential parity in the first recording area where the second potential parity is stored, in the buffer memory 80, and overwrite the third potential parity to the first recording area. If there is no need to execute the potential error correction on the data on the second track STRn using the second potential parity and the like, the second potential parity can be deleted in the buffer memory 80 and the second potential parity can be updated to the third potential parity in the buffer memory 80. This can contribute to the efficient recording of the potential parity.

In contrast, if the second prediction information is replaced with abnormal information for predicting that the second conventional error correction may reach its limit, the storage processing unit 65 can change the recording area where the potential parity is stored, in the buffer memory 80, leave the second potential parity in the first recording area, and set the second recording area which is different from the first recording area, in the buffer memory 80, as the recording area where the third potential parity is stored.

Alternatively, the storage processing unit 65 can leave the second potential parity in the second recording area of the buffer memory 80 and set the third recording area which is different from the first recording area and the second recording area, in the buffer memory 80, as the recording area where the third potential parity is stored.

If it is necessary to execute the potential error correction on the data in the second track STRn using the second potential parity and the like, the second potential parity can be left in the buffer memory 80.

Next, a case where the first prediction information is normal information and a case where the first prediction information is replaced with abnormal information will be described.

The first track STR(n−1) is located in the first direction Da as viewed from the second track STRn, in the direction parallel to the radial direction d1.

During a second write period when data is written to the second track STRn, the conventional correction limit prediction unit 66 can determine whether the position of the write head WHD is beyond the first limit radius position PO1 in the first direction Da. The first limit radius position PO1 is the position offset by the write-off track slice WOS1 from the track center STCn of the second track STRn in the first direction Da.

As a result, if the position of the write head WHD is not displaced beyond the first limit radius position PO1 in the first direction Da, the first prediction information becomes normal information. In contrast, if the position of the write head WHD is displaced beyond the first limit radius position PO1 in the first direction Da, the first prediction information is replaced with abnormal information.

Next, a case where the second prediction information is normal information and a case where the second prediction information is replaced with abnormal information will be described.

The third track STR(n+1) is located in the second direction Db opposite to the first direction Da as viewed from the second track STRn, in the direction parallel to the radial direction d1.

During a second write period when data is written to the second track STRn, the conventional correction limit prediction unit 66 can determine whether the position of the write head WHD is displaced beyond the second limit radius position PO2 in the second direction Db. The second limit radius position PO2 is the position offset by the write-off track slice WOS2 from a track center STCn of the second track STRn in the second direction Db.

As a result, if the position of the write head WHD is not displaced beyond the second limit radius position PO2 in the second direction Db, the second prediction information becomes normal information. In contrast, if the position of the write head WHD is displaced beyond the second limit radius position PO2 in the second direction Db, the second prediction information is replaced with abnormal information.

Next, conditions for a boundary between the normal information and the abnormal information will be described by focusing the total amount of displacement of the write head WHD.

During the second write period, the conventional correction limit prediction unit 66 can calculate the amount of displacement of the position of the write head WHD beyond the first referential radius position in the first direction Da each time the data is written to each target sector RSC of the second track STRn, and update the total amount of the displacement during the second write period.

The first prediction information is the normal information until the total amount reaches the first reference value. In this case, even if corrupted data occurs in the first track STR(n−1), the error correction unit 64 can correct errors of the corrupted data of the track STR(n−1) by executing track-based conventional error correction.

In contrast, when the above total amount reaches the first reference value, the first prediction information is replaced with abnormal information. In this case, the error correction unit 64 can correct errors of the corrupted data of the track STR(n−1) by executing track-based potential error correction.

Next, conditions for a boundary between the normal information and the abnormal information will be described by focusing the number of one or more corrupted target sectors CSC of the track STR.

During the second write period, the conventional correction limit prediction unit 66 can manage the number of one or more corrupted target sectors CSC of the first track STR(n−1).

The first prediction information is the normal information until the number reaches the first threshold value. In this case, even if corrupted data occurs in the first track STR(n−1), the error correction unit 64 can correct errors of the corrupted data of the track STR(n−1) by executing track-based conventional error correction.

In contrast, when the above number reaches the first threshold value, the first prediction information is replaced with abnormal information. In this case, the error correction unit 64 can correct errors of the corrupted data of the track STR(n−1) by executing track-based potential error correction.

For example, if the first threshold value is “5” (five), the error correction unit 64 may select the track-based conventional error correction when four or fewer elements of the corrupted data occur on the first track STR(n−1). Then, when five or more elements of corrupted data occur on the first track STR(n−1), the error correction unit 64 may select the track-based potential error correction.

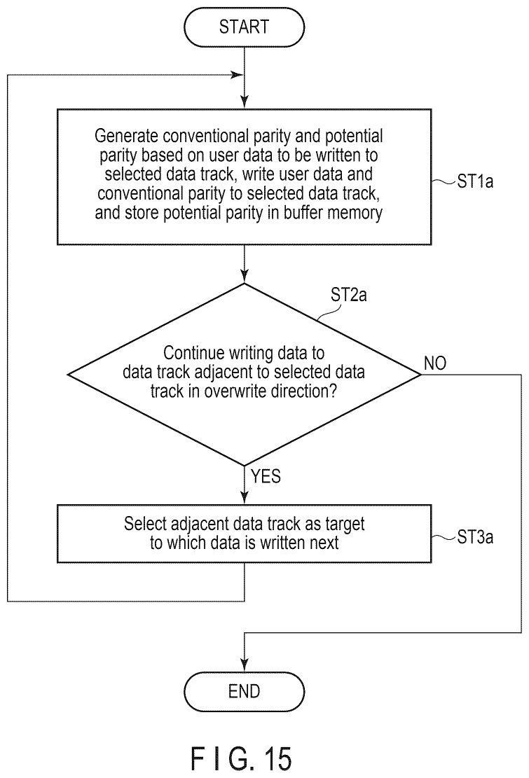

Next, the operations of the write processing unit 62, the parity generation unit 4W4, and the storage processing unit 65 in a case of sequentially writing the data to the plurality of tracks STR will be described. FIG. 15 is a flowchart showing a write processing method according to the embodiment, together with the generation of the potential parity and the storage of the potential parity.

As shown in FIG. 15, when the write processing starts, first, the conventional parity and the potential parity are generated based on the user data to be written to the selected data track, the user data and the conventional parity are written to the selected data track, and the potential parity is stored in the buffer memory 80, in step ST1a.

For example, when the first track STR(n−1) in FIG. 10 is selected, the parity generation unit 4W4 generates the first conventional parity and the first potential parity based on the first user data to be written to the first track STR(n−1), and the write processing unit 62 writes the first user data and the first conventional parity to the first track STR(n−1), and the storage processing unit 65 stores the first potential parity in the buffer memory 80.

Next, whether to continue writing the data to the data track adjacent to the selected data track in the overwrite direction d5 is determined in step ST2a. For example, the write processing unit 62 determines whether to continue writing the data to the second track STRn.

If writing the data is not continued (step ST2a, NO), the write processing is terminated.

In contrast, if writing the data is continued (step ST2a, YES), the processing shifts to step ST3a, and the adjacent data track is selected as a next target to which the data is to be written. For example, the write processing unit 62 selects the second track STRn as the next target to which the data is to be written, and the processing shifts to step ST1a.

If writing the data is continued (step ST2a, YES), the processing in step ST3a and step ST1a may be repeated.

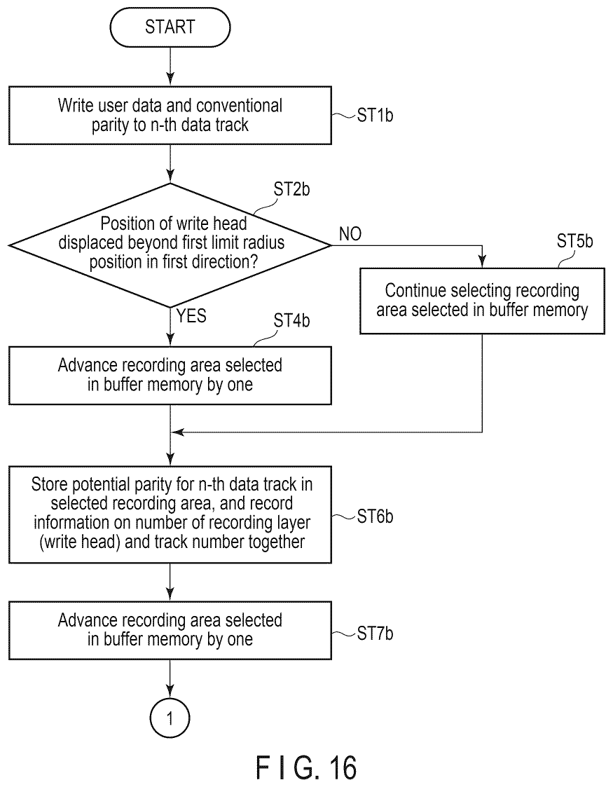

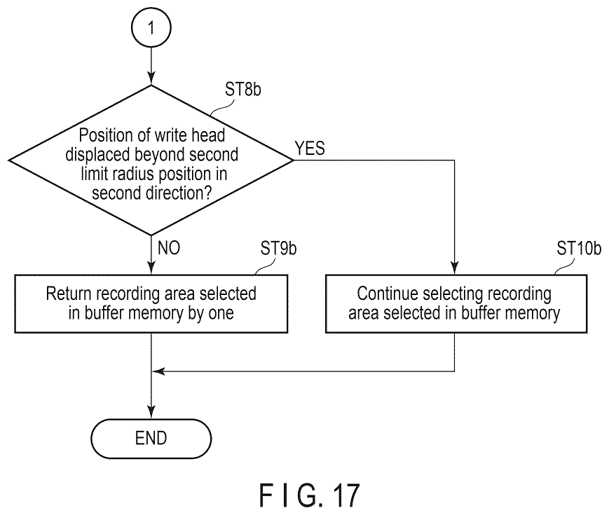

Next, the operations of the write processing unit 62, the parity generation unit 4W4, the storage processing unit 65, and the conventional correction limit prediction unit 66 in a case of writing the data to the n-th track STR after writing the data to the n−1-th track STR will be described. FIG. 16 is a flowchart showing the write processing method for the n-th data track, of the write processing method according to the embodiment, together with a method of storing a potential parity in the buffer memory 80. FIG. 17 is a flowchart showing the write processing method following FIG. 16, together with the storing method.

As shown in FIG. 16, when the write processing for the n-th track STR is started, first, the write processing unit 62 writes the user data and the conventional parity to the n-th track STR, in step ST1b. Next, in step ST2b, the conventional correction limit prediction unit 66 determines whether the position of the write head WHD is displaced beyond the first limit radius position on the n−1-th track STR side, in the first direction Da.

If the write head WHD is displaced (step ST2b, YES), the processing shifts to step ST4b, and the storage processing unit 65 advances the selected recording area in the buffer memory 80 by one and the processing shifts to step ST6b.

If the write head WHD is not displaced (step ST2b, NO), the processing shifts to step ST5b, the storage processing unit 65 continuously selects the recording area currently selected in the buffer memory 80, and the processing shifts to step ST6b.

In step ST6b, the storage processing unit 65 stores the potential parity for the n-th track STR in the selected recording area, and records the information on the number of the recording layer L (write head WHD) and the track number together. Then, in step ST7b, the storage processing unit 65 advances the selected recording area in the buffer memory 80 by one, and the processing shifts to step ST8b.

After that, in step ST8b, as shown in FIG. 17, the conventional correction limit prediction unit 66 determines whether the position of the write head WHD is displaced beyond the second limit radius position on the n+1-th track STR side, in the second direction Db (opposite to the first direction Da). If the write head WHD is not displaced (step ST8b, NO), the processing shifts to step ST9b, the storage processing unit 65 moves back one recording area to be selected in the buffer memory 80, and ends the write processing for the n-th track STR.

In contrast, if the write head WHD is displaced (step ST8b, YES), the processing shifts to step ST10b, the storage processing unit 65 continues selecting the recording area currently selected in the buffer memory 80, and ends the write processing for the n-th track STR. As understood from the descriptions using FIG. 16 and FIG. 17, since the magnetic disk device 1 of the embodiment can execute the processing of step ST5b, step ST9b, and step ST10b as necessary, the potential parity can be efficiently recorded.

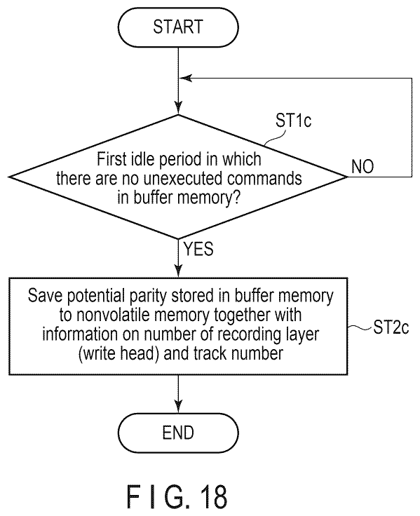

Next, a method of saving the potential parity to the nonvolatile memory 90 during idle periods will be described. FIG. 18 is a flowchart showing a method of saving the potential parity in the nonvolatile memory 90 during a first idle period, in the embodiment.

As shown in FIG. 18, when the method of saving the potential parity to the nonvolatile memory 90 is started, first, the determination unit 68 determines whether the current period is the first idle period in which there are no unexecuted commands in the buffer memory 80, in step ST1c. If the current period is not the first idle period (step ST1c, NO), the determination unit 68 repeatedly executes the processing in step ST1c.

In contrast, if the current period is the first idle period (step ST1c, YES), the processing shifts to step ST2c, and the storage processing unit 65 saves the potential parity stored in the buffer memory 80 to the nonvolatile memory 90 together with the information on the number of the recording layer L (write head WHD) and the track number. The method of saving the potential parity to the nonvolatile memory 90 is thereby ended.

Incidentally, the potential parity saved to the nonvolatile memory 90 is different in a case where the first prediction information is the normal information and a case where the first prediction information is replaced with the abnormal information. For example, if the first prediction information is the normal information, the second potential parity is overwritten to the first recording area of the buffer memory 80, and the first potential parity is updated to the second potential parity in the buffer memory 80. Therefore, the storage processing unit 65 can save the second potential parity stored in the buffer memory 80, to the nonvolatile memory 90.

Alternatively, if the first prediction information is replaced with the abnormal information, the first potential parity is left in the first recording area of the buffer memory 80, and the second potential parity is stored in the second recording area in the buffer memory 80. Therefore, the storage processing unit 65 can save the first potential parity and the second potential parity stored in the buffer memory 80, to the nonvolatile memory 90. The potential parity is thereby ensured.

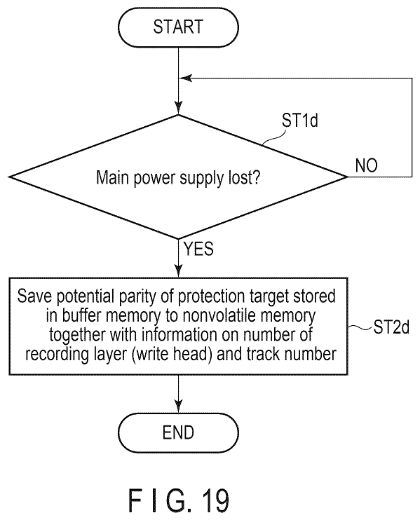

Next, the PLP processing of ensuring the potential parity which is the protection target in the buffer memory 80 will be described. FIG. 19 is a flowchart showing a method of saving the potential parity to the nonvolatile memory 90 when the main power supply 5 is lost, in the embodiment.

As shown in FIG. 19, when the PLP processing of ensuring the potential parity which is the protection target in the buffer memory 80 is started, first, the management unit 69A determines whether the main power supply 5 is lost, in step ST1d. If the main power supply 5 is not lost (step ST1d, NO), the management unit 69A repeatedly executes the processing in step ST1d.

In contrast, if the main power supply 5 is lost (step ST1d, YES), the processing shifts to step ST2d, and the storage processing unit 65 saves the potential parity which is the protection target in the buffer memory 80 to the nonvolatile memory 90 together with the information on the number of the recording layer L (write head WHD) and the track number. As a result, the PLP processing of ensuring the potential parity which is the protection target in the buffer memory 80 is ended.

Incidentally, the potential parity saved to the nonvolatile memory 90 is different in a case where the first prediction information is the normal information and a case where the first prediction information is replaced with the abnormal information. For example, if the first prediction information is the normal information, the storage processing unit 65 can save the second potential parity stored in the buffer memory 80, to the nonvolatile memory 90.

Alternatively, if the first prediction information is replaced with the abnormal information, the storage processing unit 65 can save the first potential parity and the second potential parity stored in the buffer memory 80, to the nonvolatile memory 90. The potential parity is thereby ensured.

Next, the potential error correction executed by the error correction unit 64 will be described.

As shown in FIG. 1 and FIG. 10, it is assumed that the first prediction information is replaced with the abnormal information. The determination unit 68 can determine whether the period is the second idle period in which there are no unexecuted commands in the buffer memory 80, after the first idle period.

When the determination unit 68 determines that the period is the second idle period, the error correction unit 64 can execute the error correction of the first corrupted data of the first track STR(n−1), based on the first user data of the first track STR(n−1), the first conventional parity, and the first potential parity, restore the data in the first track STR(n−1), and rewrite the restored data to the first track STR(n−1).

Next, the write processing of Example 1 of the embodiment will be described.

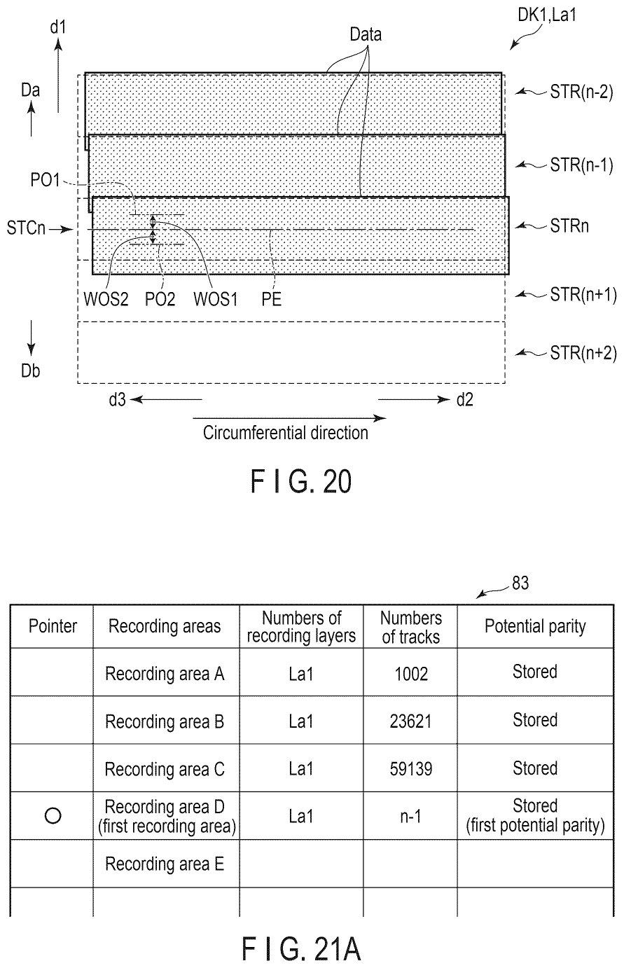

FIG. 20 is a schematic diagram showing five data tracks of the recording layer La1 of the disk DK1 shown in FIG. 10, illustrating a state in which the data is written to the n−2-th data track, the n−1-th data track, and the n-th data track in order, and illustrating a situation in which the write processing is ideally executed without positioning errors.

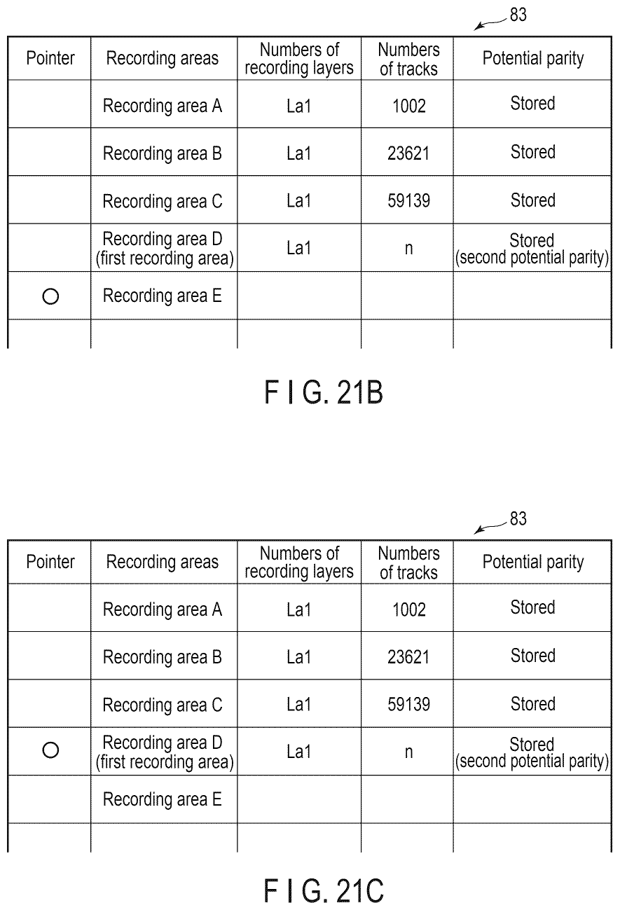

FIG. 21A is a table showing the recording area 83 of the buffer memory 80, illustrating a method of storing the potential parity in the buffer memory 80 corresponding to the write processing in FIG. 20, and illustrating a state in which the first potential parity is stored in the currently selected first recording area and then the currently selected first recording area is continuously selected.

FIG. 21B is a table showing the recording area 83 of the buffer memory 80 following FIG. 21A, illustrating a situation in which the second potential parity is overwritten to the currently selected first recording area and then the recording area selected in the buffer memory 80 is advanced by one.

FIG. 21C is a table showing the recording area 83 of the buffer memory 80, following FIG. 21B, illustrating a situation in which the selected recording area in the buffer memory 80 is moved back by one.

As shown in FIG. 20 and FIG. 21A, the positioning error PE is not displaced beyond the first limit radius position PO1 in the first direction Da during the write processing to the second track STRn. Therefore, as shown in step ST5b of FIG. 16, the storage processing unit 65 continues selecting a recording area D (first recording area) currently selected in the buffer memory 80.

As shown in FIG. 20 and FIG. 21B, the storage processing unit 65 stores the second potential parity in the currently selected recording area D and records the information on the number of the recording layer La1 (write head WHD1) and the track number n together (FIG. 16, step ST6b). Next, the storage processing unit 65 advances the recording area selected in the buffer memory 80 by one from the recording area D to a recording area E (FIG. 16, step ST7b). In other words, the storage processing unit 65 can advance the pointer by one.

As shown in FIG. 20 and FIG. 21C, the positioning error PE is not displaced beyond the second limit radius position PO2 in the second direction Db during the write processing to the second track STRn. Therefore, as shown in step ST9b of FIG. 17, the storage processing unit 65 moves the recording area currently selected in the buffer memory 80 back by one from the recording area E to the recording area D. In other words, the storage processing unit 65 can move the pointer back by one. Therefore, an option to overwrite the third potential parity to the recording area D can be created.

Next, the write processing of Example 2 of the embodiment will be described.

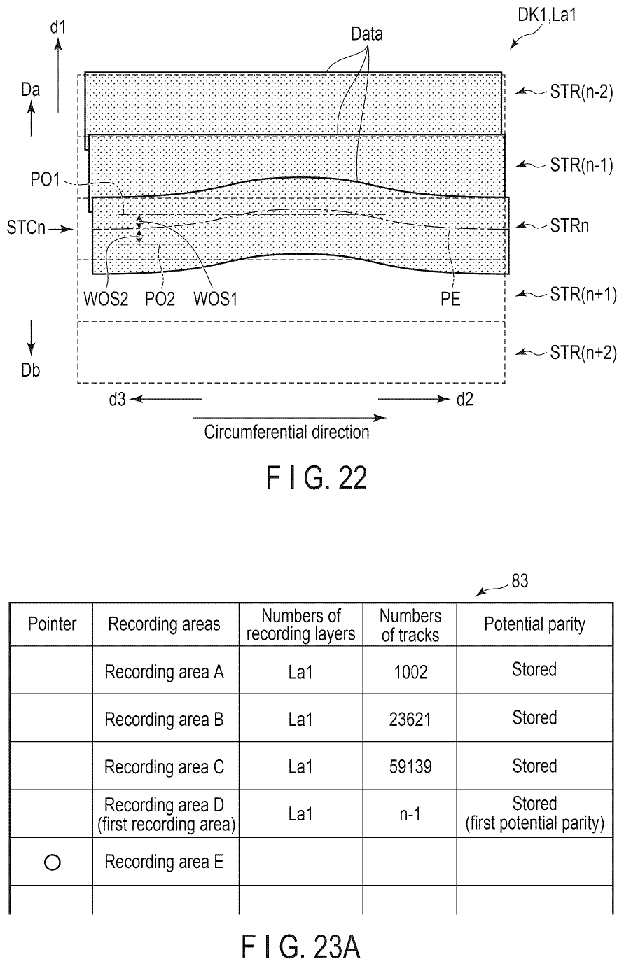

FIG. 22 is a schematic diagram showing five data tracks of the recording layer La1 of the disk DK1 shown in FIG. 10, illustrating a state in which the data is written to the n−2-th data track, the n−1-th data track, and the n-th data track in order, and illustrating a situation in which the write processing is being executed on the n-th data track while the positioning error PE exceeds the first off-track slice WOS1.

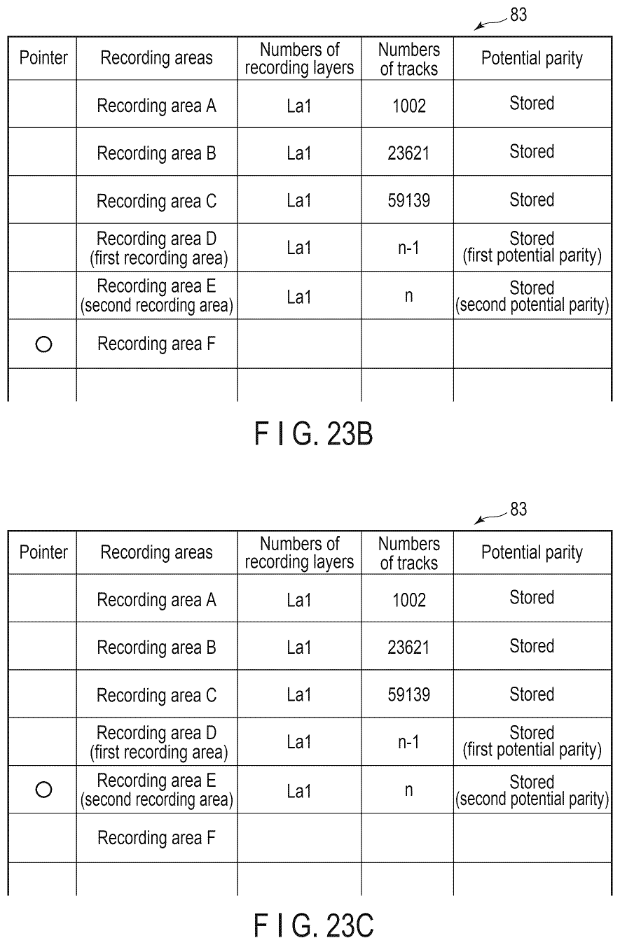

FIG. 23A is a table showing the recording area 83 of the buffer memory 80, illustrating a method of storing the potential parity in the buffer memory 80 corresponding to the write processing in FIG. 22, and illustrating a situation in which the first potential parity is stored in the currently selected first recording area and then the recording area selected in the buffer memory 80 is advanced by one.

FIG. 23B is a table showing the recording area 83 of the buffer memory 80, following FIG. 23A, illustrating a situation in which the second potential parity is stored in the currently selected second recording area and then the recording area selected in the buffer memory 80 is advanced by one.

FIG. 23C is a table showing the recording area 83 of the buffer memory 80, following FIG. 23B, illustrating a situation in which the selected recording area selected in the buffer memory 80 is moved back by one.

As shown in FIG. 22 and FIG. 23A, the positioning error PE is displaced beyond the first limit radius position PO1 in the first direction Da during the write processing to the second track STRn (FIG. 16, step ST2b, YES). In addition, the first potential parity is stored in the selected recording area D (FIG. 16, step ST3b, YES). Therefore, as shown in step ST4b of FIG. 16, the storage processing unit 65 advances the recording area currently selected in the buffer memory 80 by one from the recording area D (first recording area) to the recording area E.

As shown in FIG. 22 and FIG. 23B, the storage processing unit 65 stores the second potential parity in the currently selected recording area E (second recording area) and records the information on the number of the recording layer La1 (write head WHD1) and the track number n together (FIG. 16, step ST6b). Next, the storage processing unit 65 advances the recording area selected in the buffer memory 80 by one from the recording area E to a recording area F (FIG. 16, step ST7b).

As shown in FIG. 22 and FIG. 23C, the positioning error PE is not displaced beyond the second limit radius position PO2 in the second direction Db during the write processing to the second track STRn. Therefore, as shown in step ST9b of FIG. 17, the storage processing unit 65 moves the recording area currently selected in the buffer memory 80 back by one from the recording area F to the recording area E. Therefore, the first potential parity can be left in the recording area D, and an option to overwrite the third potential parity to the recording area E can be created.

Next, the write processing of Example 3 of the embodiment will be described.

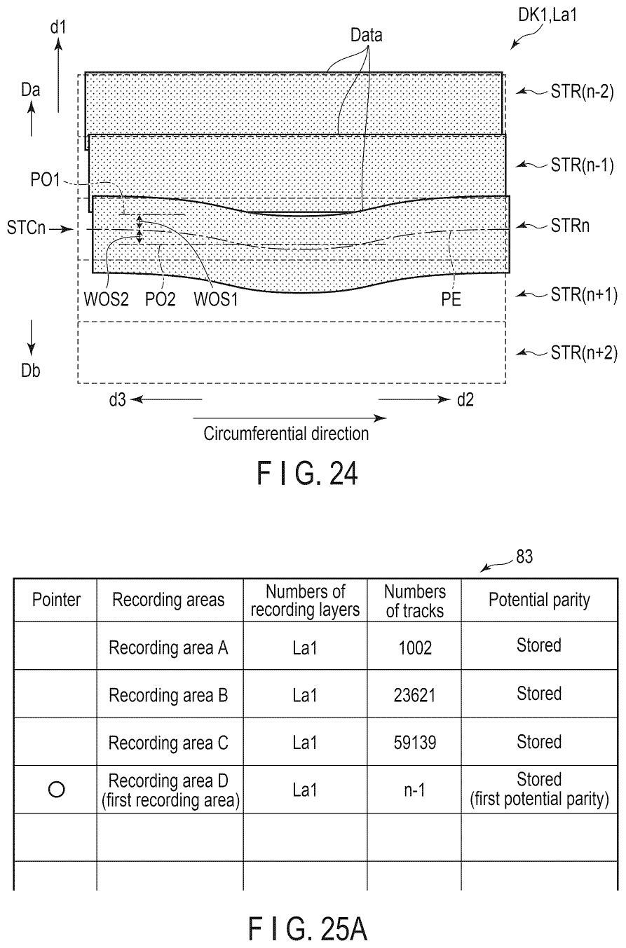

FIG. 24 is a schematic diagram showing five data tracks of the recording layer La1 of the disk DK1 shown in FIG. 10, illustrating a state in which the data is written to the n−2-th data track, the n−1-th data track, and the n-th data track in order, and illustrating a situation in which the write processing is being executed on the n-th data track while the positioning error PE exceeds the second off-track slice WOS2.

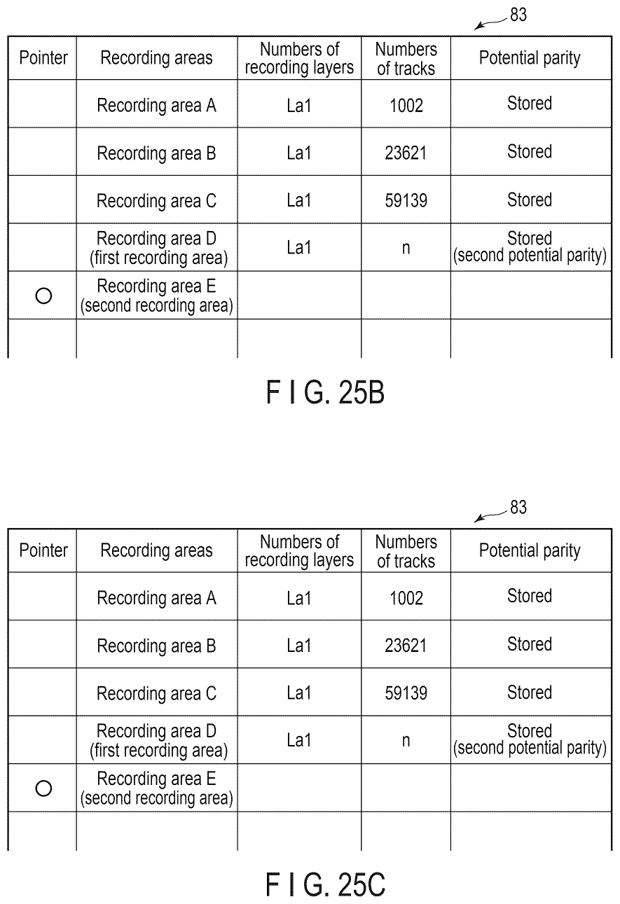

FIG. 25A is a table showing the recording area 83 of the buffer memory 80, illustrating a method of storing the potential parity in the buffer memory 80 corresponding to the write processing in FIG. 24, and illustrating a state in which the first potential parity is stored in the currently selected first recording area and then the currently selected first recording area is continuously selected.

FIG. 25B is a table showing the recording area 83 of the buffer memory 80, following FIG. 25A, illustrating a situation in which the second potential parity is stored in the currently selected first recording area and then the recording area selected in the buffer memory 80 is advanced by one.

FIG. 25C is a table showing the recording area 83 of the buffer memory 80, following FIG. 25B, illustrating a situation in which the second recording area currently selected in the buffer memory 80 is continuously selected.

As shown in FIG. 24 and FIG. 25A, the positioning error PE is not displaced beyond the first limit radius position PO1 in the first direction Da during the write processing to the second track STRn (FIG. 16, step ST2b, NO). Therefore, as shown in step ST5b of FIG. 16, the storage processing unit 65 continues selecting a recording area D (first recording area) currently selected in the buffer memory 80.

As shown in FIG. 24 and FIG. 25B, the storage processing unit 65 stores the second potential parity in the currently selected recording area D (first recording area) and records the information on the number of the recording layer La1 (write head WHD1) and the track number n together (FIG. 16, step ST6b). Next, the storage processing unit 65 advances the recording area selected in the buffer memory 80 by one from the recording area D to a recording area E (FIG. 16, step ST7b).

As shown in FIG. 24 and FIG. 25C, the positioning error PE is displaced beyond the second limit radius position PO2 in the second direction Db during the write processing to the second track STRn. Therefore, as shown in step ST10b of FIG. 17, the storage processing unit 65 continues selecting the recording area E (second recording area) currently selected in the buffer memory 80. Therefore, the second potential parity can be left in the recording area D.

According to the magnetic disk device 1 of the embodiment configured as described above, the magnetic disk device 1 comprises the disk DK, the write head WHD, the buffer memory 80, the parity generation unit 4W4, the write processing unit 62, the error correction unit 64, the storage processing unit 65, and the conventional correction limit prediction unit 66. The error correction unit 64 can execute the error correction of the data in the corrupted target sector CSC in which the data is determined to be corrupted, among the plurality of target sectors RSC on each of the first track STR(n−1) and the second track STRn.

The write processing unit 62 can write the first user data to the plurality of target sectors RSC of the first track STR(n−1) and use the sectors as the plurality of user data sectors, during the first write period. The write processing unit 62 can write the second user data to the plurality of target sectors RSC of the second track STRn and use the sectors as the plurality of user data sectors, during the second write period following the first write period.

The parity generation unit 4W4 can generate the first conventional parity and the first potential parity for error correction of the first corrupted data of the first track STR(n−1), and generate the second conventional parity and the second potential parity for error correction of the second corrupted data of the second track STRn.

The storage processing unit 65 can store the first potential parity in the buffer memory 80, and then store the second potential parity in the buffer memory 80. The conventional correction limit prediction unit 66 can generate the first prediction information after the second user data is written to the second track STRn.

If the first prediction information is the normal information, the storage processing unit 65 can maintain the recording area where the potential parity is stored, in the buffer memory 80, store the second potential parity in the first recording area where the first potential parity is stored, in the buffer memory 80, and overwrite the second potential parity to the first recording area.

If the first prediction information is replaced with the abnormal information, the storage processing unit 65 can change the recording area where the potential parity is stored, in the buffer memory 80, leave the first potential parity in the first recording area, and store the second potential parity in the second recording area which is different from the first recording area, in the buffer memory 80.

Based on the above, it is possible to efficiently record the parity and obtain the magnetic disk device 1 that is excellent in its ability to correct errors in user data on the disk DK.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above-described technology may be applied not only to the magnetic disk devices of the hybrid recording type, but also to the magnetic disk devices of the shingled magnetic recording type and the magnetic disk devices of the conventional magnetic recording type.

What is claimed is

1. A magnetic disk device comprising:
a disk including a user data area including a first data track and a second data track continuous in a radial direction, in a recording layer, the first data track and the second data track each including a plurality of target sectors as targets to which data is written;
a write head writing data to the recording layer of the disk;
a volatile buffer memory;
a parity generation unit;
a write processing unit capable of executing write processing of writing data to the recording layer;
an error correction unit executing error correction of data of a corrupted target sector in which data is determined to be corrupted among the plurality of target sectors of each of the first data track and the second data track;
a storage processing unit; and
a conventional correction limit prediction unit,
wherein
the write processing unit writes first user data to the plurality of target sectors of the first data track and uses the target sectors as a plurality of user data sectors, during a first write period,
the write processing unit writes second user data to the plurality of target sectors of the second data track and uses the target sectors as a plurality of user data sectors, during a second write period following the first write period,
the parity generation unit generates first conventional parity and first potential parity for error correction of first corrupted data of one or more corrupted target sectors of the first data track, based on the first user data,
an ability of the first potential parity to execute error correction of the first corrupted data is higher than an ability of the first conventional parity to execute error correction of the first corrupted data,
the parity generation unit generates second conventional parity and second potential parity for error correction of second corrupted data of one or more corrupted target sectors of the second data track, based on the second user data,
an ability of the second potential parity to execute error correction of the second corrupted data is higher than an ability of the second conventional parity to execute error correction of the second corrupted data,
the storage processing unit stores the first potential parity in the buffer memory, and then stores the second potential parity in the buffer memory,
the conventional correction limit prediction unit generates first prediction information that is the information for predicting whether the first conventional error correction of the first corrupted data, which is executed using the first conventional parity by the error correction unit, reaches its limit after the second user data is written to the second data track,
if the first prediction information is normal information for predicting that the first conventional error correction does not reach its limit, the storage processing unit maintains a recording area where the potential parity is stored, in the buffer memory, stores the second potential parity in the first recording area where the first potential parity is stored, in the buffer memory, and overwrites the second potential parity to the first recording area, and
if the first prediction information is replaced with abnormal information for predicting that the first conventional error correction reaches its limit, the storage processing unit changes the recording area where the potential parity is stored, in the buffer memory, leaves the first potential parity in the first recording area, and stores the second potential parity in the second recording area which is different from the first recording area, in the buffer memory.

2. The magnetic disk device of claim 1, wherein
the first data track is located in a first direction as viewed from the second track, in a direction parallel to the radial direction of the disk,
the conventional correction limit prediction unit determines whether a position of the write head is displaced beyond a first limit radius position in the first direction, during the second write period,
if the position of the write head is not displaced beyond the first limit radius position in the first direction, the first prediction information is the normal information, and
if the position of the write head is displaced beyond the first limit radius position in the first direction, the first prediction information is replaced with the abnormal information.

3. The magnetic disk device of claim 2, wherein
the conventional correction limit prediction unit calculates an amount of displacement of the position of the write head beyond the first referential radius position in the first direction each time the data is written to each of the target sectors of the second data track, during the second write period, and updates a total amount of the displacement during the second write period,
the first prediction information is the normal information until the total amount reaches a first reference value, and
when the total amount reaches the first reference value, the first prediction information is replaced with the abnormal information.

4. The magnetic disk device of claim 2, wherein
the conventional correction limit prediction unit manages number of the one or more corrupted target sectors of the first data track, during the second write period,
the first prediction information is the normal information until the number reaches a first threshold value, and
when the number reaches the first threshold value, the first prediction information is replaced with the abnormal information.

5. The magnetic disk device of claim 1, wherein
the user data area further includes a third data track continuous with the second data track in the radial direction, and the third data track includes the plurality of target sectors,
the error correction unit executes error correction of data of a corrupted target sector in which data is determined to be corrupted among the plurality of target sectors of the third data track,
the write processing unit writes the third user data to the plurality of target sectors of the third data track and uses the sectors as a plurality of user data sectors, during a third write period following the second write period,
the parity generation unit generates third conventional parity and third potential parity for error correction of third corrupted data of one or more corrupted target sectors of the third data track, based on the third user data,
an ability of the third potential parity to execute error correction of the third corrupted data is higher than an ability of the third conventional parity to execute error correction of the third corrupted data,
the storage processing unit stores the third potential parity in the buffer memory after storing the second potential parity in the buffer memory,
the conventional correction limit prediction unit generates second prediction information that is the information for predicting whether the second conventional error correction of the second corrupted data, which is executed using the second conventional parity by the error correction unit, reaches its limit after the second user data is written to the second data track,
if the second prediction information is normal information for predicting that the second conventional error correction does not reach its limit, the storage processing unit
maintains a recording area where the potential parity is stored, in the buffer memory, and
sets the first recording area where the second potential parity is stored as a recording area where the third potential parity is overwritten, or sets the second recording area where the second potential parity is stored as the recording area where the third potential parity is overwritten, and
if the second prediction information is replaced with abnormal information for predicting that the second conventional error correction reaches its limit, the storage processing unit
changes the recording area where the potential parity is stored, in the buffer memory, and
leaves the second potential parity in the first recording area and sets the second recording area as a recording area where the third potential parity is stored, or
leaves the second potential parity in the second recording area and sets a third recording area different from the first recording area and the second recording area as the recording area where the third parity is stored, in the buffer memory.

6. The magnetic disk device of claim 5, wherein
the first data track is located in a first direction as viewed from the second data track, and the third data track is located in a second direction opposite to the first direction as viewed from the second data track, in a direction parallel to a radial direction of the disk,
the conventional correction limit prediction unit determines whether a position of the write head is displaced beyond a second limit radius position in the second direction, during the second write period,
if the position of the write head is not displaced beyond the second limit radius position in the second direction, the second prediction information is the normal information, and
if the position of the write head is displaced beyond the second limit radius position in the second direction, the second prediction information is replaced with the abnormal information.

7. The magnetic disk device of claim 1, further comprising:
a command execution unit executing a write command and a read command recorded in the buffer memory;
a nonvolatile memory; and
a determination unit,
wherein
when the determination unit determines a first idle period in which there are no unexecuted commands in the buffer memory, the storage processing unit
saves the second potential parity stored in the buffer memory, to the nonvolatile memory, if the first prediction information is the normal information, or
saves the first potential parity and the second potential parity stored in the buffer memory, to the nonvolatile memory, if the first prediction information is replaced with the abnormal information.

8. The magnetic disk device of claim 7, further comprising:
a read head reading data from the recording layer of the disk; and
a read processing unit capable of read processing of reading data from the recording layer,
wherein
when the first prediction information is in a state of being replaced with the abnormal information, and when the determination unit determines a second idle period in which there are no unexecuted commands in the buffer memory after the first idle period, the error correction unit executes error correction of the first corrupted data, based on the first user data, the first conventional parity, and the first potential parity of the first data track, restores the data of the first data track, and rewrites the restored data to the first data track.

9. The magnetic disk device of claim 1, further comprising:
a nonvolatile memory;
a main power supply;
a management unit adding potential parity before saving to the nonvolatile memory, to protection targets, and excluding a potential parity after saving to the nonvolatile memory from the protection targets, among potential parities stored in the buffer memory; and
a data protection processing unit saving the potential parity managed as the protection target by the management unit to the nonvolatile memory when the main power supply is lost,
wherein
if the first prediction information is the normal information, the potential parity stored in the buffer memory is the second potential parity, and
if the first prediction information is the abnormal information, the potential parity stored in the buffer memory is the first potential parity and the second potential parity.

10. The magnetic disk device of claim 1, wherein
a data length of the first potential parity is longer than a data length of the first conventional parity and is shorter than a data length of the first user data written to the plurality of user data sectors of the first data track, and
a data length of the second potential parity is longer than a data length of the second conventional parity and is shorter than a data length of the second user data written to the plurality of user data sectors of the second data track.

11. The magnetic disk device of claim 1, wherein
the second data track is located in a second direction as viewed from the first data track, in a direction parallel to the radial direction, and
the write processing unit is capable of selecting shingled magnetic recording of writing data to the first data track and the second data track in order while overlapping in the second direction, and executing write processing.
